(19) United States
(12) Patent Application Publication
(10) Pub. No.: US 2026/0304838 A1
(43) Pub. Date: Oct. 1, 2026

(54) SEMICONDUCTOR DEVICE AND ELECTRONIC APPARATUS

(71) Applicant: IDEMITSU KOSAN CO., LTD., Tokyo (JP)

(72) Inventors: Yuki TSURUMA, Chiyoda-ku, Tokyo (JP); Hiroyuki MIWA, Chiyoda-ku, Tokyo (JP); Hisanori NAGATOMI, Chiyoda-ku, Tokyo (JP); Emi KAWASHIMA, Chiyoda-ku, Tokyo (JP); Nobuhiro IWASE, Chiyoda-ku, Tokyo (JP)

(73) Assignee: IDEMITSU KOSAN CO., LTD., Tokyo (JP)

(21) Appl. No.: 19/476,440

(22) PCT Filed: Apr. 18, 2024
(86) PCT No.: PCT/JP2024/015420

§ 371 Date: Oct. 17, 2025

(30) Foreign Application Priority Data
Apr. 19, 2023 (JP) 2023-068895

(51) Int. Cl. H10D 30/67; H10D 30/01; H10D 62/60; H10W 20/41

(52) U.S. Cl. CPC H10D 30/6731; H10D 30/6734; H10D 30/6755; H10D 62/60; H10D 30/0314; H10W 20/435

(57) ABSTRACT

This semiconductor device includes a thin film transistor comprising, on a substrate: an oxide semiconductor layer, which comprises an impurity region containing boron as an impurity and a channel region, and in which an atomic ratio of In to all metal elements is 70 atom % or more; a plurality of insulating film layers; and a plurality of metal layers. The linear mobility μₗᵢₙ of the thin film transistor is 15 cm²/Vs or more and the threshold voltage Vth of the thin film transistor is more than −2.4 V.

### CROSS-REFERENCE TO RELATED APPLICATIONS

The present application claims priority under 35 U.S.C. § 371 to International Patent Application No. PCT/JP2024/015420, filed Apr. 18, 2024, which claims priority to and the benefit of Japanese Patent Application No. 2023-068895, filed on Apr. 19, 2023. The contents of these applications are hereby incorporated by reference in their entireties.

### TECHNICAL FIELD

The present invention relates to a semiconductor device and an electronic apparatus.

### BACKGROUND ART

A thin film transistor (TFT) using an oxide semiconductor for a channel layer is widely used industrially.

In recent years, a TFT tends to be reduced in size, and characteristics of a small TFT have been important.

For example, in driving of a high-definition display, high mobility and stable TFT characteristics are required.

For example, Patent Document 1 discloses that a thin film transistor including a gate electrode and an oxide semiconductor having an impurity element in a region not overlapping a source electrode and a drain electrode is provided, so that a transistor having a reduced parasitic resistance of the transistor and a high on-current can be obtained.

Meanwhile, Patent Document 2 discloses that a thin film transistor including an oxide semiconductor containing In at a high amount (for example, the amount of In is 92 atom % based on all metal elements) can continue to operate without causing a decrease in mobility even by long-time operation.

### RELATED ART DOCUMENTS

### Patent Documents

[Patent Document 1] JP 2022-169558 A
[Patent Document 2] JP 2015-103646 A

### SUMMARY OF INVENTION

Hitherto, an oxide semiconductor having the indium-containing amount of less than 70 atom % has been widely applied to industry, and a semiconductor device having a low-resistance impurity region and a favorable switching region at the same time has been provided.

Meanwhile, the present applicant has provided a thin film transistor having high mobility and favorable TFT characteristics, the thin film transistor using an oxide semiconductor material having the high indium amount, that is, the indium amount of 70 atom % (hereinafter, also described as at %) or more.

However, in a thin film transistor including an oxide semiconductor layer containing indium at a high amount, an optimum state of a low-resistance impurity region in the oxide semiconductor layer has not been found.

For example, in the thin film transistor including an oxide semiconductor layer containing indium at a high amount, the effective channel length may become small (a difference between the gate width and the effective channel length may become large). For this reason, it is difficult to downsize a thin film transistor using an oxide semiconductor layer having the high amount of indium as disclosed in Patent Document 2.

An object of the present invention is to provide a semiconductor device having stable TFT characteristics by sufficiently securing an effective channel length using an oxide semiconductor material having an indium-containing amount of 70 atom % or more.

According to the present invention, the following semiconductor device and the like are provided.
1. A semiconductor device comprising a thin film transistor, wherein it comprises an oxide semiconductor layer which comprises an impurity region containing boron as an impurity, and a channel region, and in which the atomic percent of In is 70 atom % or more based on all metal elements, a plurality of insulating film layers, and a plurality of metal layers, on a substrate, wherein a linear mobility μₗᵢₙ thereof is 15 cm²/Vs or more, and a threshold voltage Vth thereof is more than −2.4 V.
2. The semiconductor device according to 1, wherein on the substrate, a first insulating layer, the oxide semiconductor layer, a second insulating layer, and a first metal layer are stacked in this order.
3. The semiconductor device according to 1 or 2, wherein the atomic percent of In is 73 atom % or more based on all metal elements contained in the oxide semiconductor layer.
4. The semiconductor device according to any one of 1 to 3, wherein the oxide semiconductor layer comprises a polycrystalline region.
5. The semiconductor device according to any one of 1 to 4, wherein the oxide semiconductor layer comprises crystal grains having a bixbyite structure.
6. The semiconductor device according to any one of 1 to 5, wherein a specific resistance of the impurity region is 0.05 Ωcm or less.
7. The semiconductor device according to any one of 1 to 6, wherein the linear mobility μₗᵢₙ of the channel region is 20 cm²/Vs or more.
8. The semiconductor device according to any one of 1 to 7, wherein an effective channel length L_{eff} of the channel region is represented by the following formula:

$${L}_{eff} = L - ( Δ {L}_{1} + Δ {L}_{2} )$$

wherein in the formula, L is a width of a gate electrode in a source electrode-drain electrode direction, ΔL₁ is a distance from a position where a perpendicular line drawn from one end portion of the gate electrode in a direction of the oxide semiconductor layer intersects the oxide semiconductor layer to an end portion of a region having a carrier concentration that functions as a channel in the oxide semiconductor layer, and ΔL₂ is a distance from a position where a perpendicular line drawn from the other end portion of the gate electrode in the direction of the oxide semiconductor layer intersects the oxide semiconductor layer to an end portion of a region having a carrier concentration that functions as a channel in the oxide semiconductor layer, and one or both of ΔL₁ and ΔL₂ are 1.1 μm or less.
9. The semiconductor device according to any one of 1 to 8, wherein an average boron concentration of the impurity region is 5×10¹⁸ to 5×10²¹ cm⁻³.
10 The semiconductor device according to any one of 2 to 9, wherein the first insulating layer is in contact with the impurity region of the oxide semiconductor layer, the first insulating layer has a first impurity-added insulating film region having a thickness up to 100 nm from an interface with the impurity region, and an average boron concentration of the first impurity-added insulating film region is 1×10¹⁷ to 3×10²¹ cm⁻³.
11. The semiconductor device according to any one of 2 to 10, wherein the second insulating layer is in contact with the impurity region on a surface of the oxide semiconductor layer on a side opposite to a contact surface with the first insulating layer, the second insulating layer has a second impurity-added insulating film region, and an average boron concentration of the second impurity-added insulating film region is 5×10¹⁸ to 5×10²¹ cm⁻³.
12. The semiconductor device according to any one of 1 to 11, wherein an average boron concentration of the channel region is less than 5×10¹⁸ cm⁻³.
13. The semiconductor device according to 11 or 12, wherein the second insulating layer comprises the second impurity-added insulating film region and a gate insulating film region having an insulating property.
14. The semiconductor device according to 13, wherein an average boron concentration of the gate insulating film region is 1×10¹⁷ to 5×10²⁰ cm⁻³.
15. The semiconductor device according to any one of 1 to 14, which is a thin film transistor.
16. An electronic circuit comprising the semiconductor device according to any one of 1 to 15.
17. An electric apparatus, an electronic apparatus, a vehicle, or a power engine, comprising the electronic circuit according to 16.

According to the present invention, it is possible to provide a semiconductor device having stable TFT characteristics by sufficiently securing an effective channel length using an oxide semiconductor material having an indium-containing amount of 70 atom % or more.

### BRIEF DESCRIPTION OF DRAWINGS

FIG. 1 is a schematic cross-sectional view for explaining a configuration example of a semiconductor device according to a first embodiment of the present aspect.

FIG. 2 is a schematic cross-sectional view for explaining a modification of an oxide semiconductor layer constituting the semiconductor device of the present aspect.

FIG. 3 is a schematic cross-sectional view for explaining a configuration example of a semiconductor device according to a second embodiment of the present aspect.

FIG. 4 is a schematic cross-sectional view for explaining another configuration example of the semiconductor device according to the second embodiment of the present aspect.

FIGS. 5A-5E are a schematic view for explaining a method for producing the semiconductor device according to the first embodiment illustrated in FIG. 1.

FIGS. 6A-6F are a schematic view for explaining a method for producing the semiconductor device according to the second embodiment illustrated in FIG. 3.

FIG. 7 is a schematic cross-sectional view of an example of a TFT adopting the configuration illustrated in FIG. 1 produced by adopting an indirect-implantation-type ion implantation process.

FIG. 8 is a schematic cross-sectional view of an example of a TFT adopting the configuration illustrated in FIG. 3 produced by adopting a direct-implantation-type ion implantation process.

FIG. 9 is a schematic configuration diagram of another example of the TFT of the present embodiment.

FIG. 10 is a schematic configuration diagram of another example of the TFT of the present embodiment.

FIGS. 11A and 11B are a schematic configuration diagram of another example of the TFT of the present embodiment.

FIG. 12 is a cross-sectional view schematically illustrating a configuration of an apparatus having a semiconductor device according to an embodiment of the present invention.

FIG. 13 is a view showing depth profiles of a boron concentration, a silicon concentration, and an indium concentration of a TFT.

### DESCRIPTION OF EMBODIMENTS

The ordinal numbers “first”, “second”, and “third” used in the present specification are attached for avoiding confusion between constituents, and constituents without descriptions for numerical specification are not numerically limited.

In the present specification and the like, the term “film” or “thin film” and the term “layer” are sometimes interchangeable with each other.

In a sintered body and an oxide thin film of the present specification and the like, the term “compound” and the term “crystalline phase” are sometimes interchangeable with each other.

In the present specification, an “oxide sintered body” is sometimes simply referred to as “sintered body”.

In the present specification, a “sputtering target” is sometimes simply referred to as “target”.

In the present specification and the like, the term “electrically connected” encompasses a connection via “an object of some electric action”. Here, the “object of some electric action” is not particularly limited as long as the object allows communication of electric signals between connected components. Examples of the “object of some electric action” include an electrode, a line, a switching device (such as a transistor), a resistor, an inductor, a capacitor, other devices having various functions, and the like.

In the present specification and the like, the functions of the source and drain of a transistor may be interchanged when, for example, a transistor of different polarity is used or the direction of a current is changed during the operation of a circuit. Therefore, in the present specification and the like, the terms “source” and “drain” may be interchangeably used.

In the present description, “x to y” represents a numerical range of “x or more and y or less”. Upper limit values and lower limit values written for numerical ranges can be arbitrarily combined.

The present invention also encompasses modes obtained by combining two or more individual modes of the present invention described below.

### 1. Semiconductor Device

A semiconductor device according to the present aspect includes a plurality of insulating film layers, a plurality of metal layers, and at least one oxide semiconductor layer on a substrate.

In one embodiment, in the semiconductor device according to the present aspect, at least a first insulating layer, the oxide semiconductor layer, a second insulating layer, and a first metal layer are stacked in this order on the substrate. When the semiconductor device in this stacking order is a so-called top-gate type semiconductor device that does not have a metal layer functioning as a gate electrode between the oxide semiconductor layer and the substrate, the first insulating layer generally functions as a buffer layer, the second insulating layer functions as a gate insulating film, and the first metal layer functions as a gate electrode.

In one embodiment, in the semiconductor device according to the present aspect, at least a first metal layer, a first insulating layer, the oxide semiconductor layer, and a second insulating layer are stacked in this order on the substrate. When the semiconductor device in this stacking order is a so-called bottom gate type semiconductor device that does not have a metal layer functioning as a gate electrode on a side opposite to the first metal layer as viewed from the oxide semiconductor layer, the first metal layer functions as a gate electrode, the first insulating layer functions as a gate insulating film, and a second insulating layer generally functions as a buffer layer.

### First Embodiment

Hereinafter, a semiconductor device according to a first embodiment of the present aspect will be described.

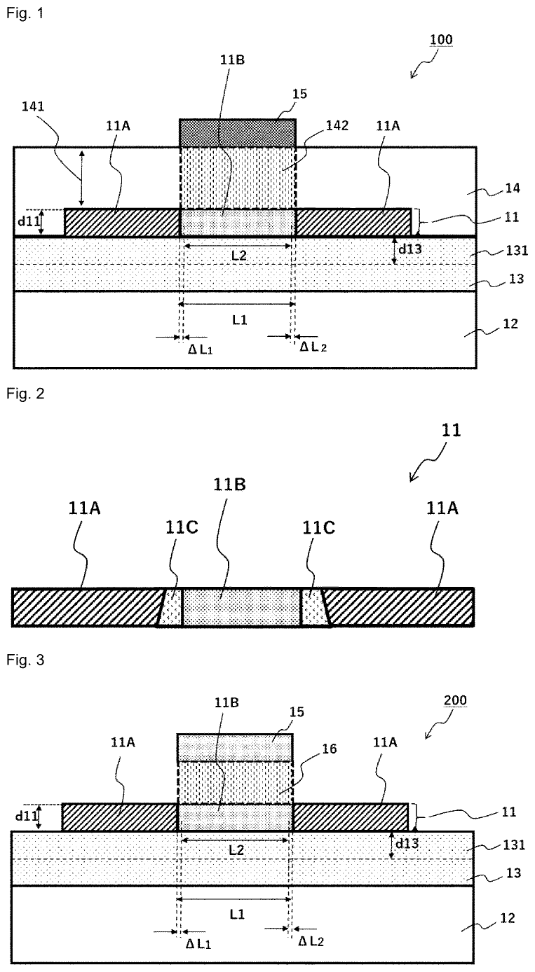

FIG. 1 is a schematic cross-sectional view for explaining a configuration example of a semiconductor device according to a first embodiment of the present aspect.

A semiconductor device 100 includes, on a substrate 12, a first insulating layer 13, an oxide semiconductor layer 11 stacked in contact with the first insulating layer 13, a second insulating layer 14 stacked in contact with the oxide semiconductor layer 11, a first metal layer 15 stacked in contact with a part of the second insulating layer 14, and a second metal layer and a third metal layer (not illustrated) connected to the oxide semiconductor layer 11.

The second metal layer and the third metal layer may be connected to the oxide semiconductor layer 11 via, for example, contact holes formed in the second insulating layer 14 and other insulating layers (not illustrated).

The oxide semiconductor layer 11 has a channel region 11B and an impurity region 11A, and the second insulating layer 14 is stacked in contact with both the channel region 11B and the impurity region 11A.

### (Oxide Semiconductor Layer)

The atomic percent of In ([In]/([In]+[all metal elements other than In])×100) is 70 at % or more based on all metal elements contained in the oxide semiconductor layer 11 in the present embodiment (hereinafter, simply referred to as the oxide semiconductor layer).

The atomic percent of In may be 71 at % or more, it may be 73 at % or more, and it may be 75 at % or more.

As the In-containing amount increases, high mobility is obtained in the semiconductor device. When 70 at % or more of the total number of atoms of the metal elements constituting the oxide semiconductor layer is In element, sufficiently high mobility can be exhibited in the semiconductor device.

The oxide semiconductor layer may be composed of a single crystal oxide semiconductor, it may be composed of a polycrystalline oxide semiconductor including a polycrystalline region, and it may be composed of an amorphous oxide semiconductor or a microcrystalline oxide semiconductor. The oxide semiconductor layer may have two or more configurations selected from the group consisting of polycrystalline, amorphous, and microcrystalline.

In one embodiment, the oxide semiconductor layer used in the present aspect is preferably composed of a polycrystalline oxide semiconductor.

An amorphous oxide semiconductor having an indium-containing amount of 70 atom % or more is likely to have difficulty in controlling a threshold voltage that is a voltage necessary for switching a transistor. It is often difficult for a single crystal oxide semiconductor to uniformly form a single crystal on a substrate having a relatively large area. On the other hand, in a polycrystalline oxide semiconductor, the difficulty as in the amorphous oxide semiconductor or the single crystal oxide semiconductor hardly occurs.

The impurity region 11A (hereinafter, simply referred to as the impurity region) contains boron as an impurity. Since the impurity region 11A contains boron, the impurity region 11A becomes a low-resistance region having a resistance value of, for example, 0.05 Ωcm or less. Therefore, by having the impurity region 11A and the channel region 11B, it is possible to have a switching region having excellent switching characteristics.

There is a tendency that the carrier concentration in the channel region 11B easily increases in the oxide semiconductor layer 11 containing indium at a high concentration; however, in the semiconductor device of the present aspect, by separating the oxide semiconductor layer 11 into the impurity region 11A containing boron as an impurity and the channel region B, Vth when the semiconductor device is driven is easily controlled to the positive side, and the semiconductor characteristics are stabilized.

Boron is different from other impurity elements, and when the impurity region 11A is formed, a case where an electron derived from oxygen deficiency generated by boron implantation into the oxide semiconductor layer is generated as a carrier and a case where an electron derived from chemical bond formation between boron and oxygen is generated as a carrier (or both of them are generated) can be appropriately selected by adjustment of implantation conditions or the like.

That is, in the impurity region 11A formed by implanting an element other than boron, only the electron derived from oxygen deficiency is a dominant carrier, but when boron is implanted as an impurity element, as described above, both the electron derived from oxygen deficiency and the electron derived from the chemical bond formation of boron can be supplied to the impurity region 11A as carriers. As a result, it is easy to find an implantation condition in which an increase in difference (ΔL₁+ΔL₂) between a gate width (L1 in FIG. 1) and an effective channel length L_{eff} (L2 in FIG. 1) is suppressed, and a low-resistance impurity region having little influence on the switching region can be obtained.

In the present specification, the “gate width” means a distance from one end portion of the gate electrode to the other end portion in the source electrode-drain electrode direction (hereinafter, referred to as “gate width L”). For example, in FIG. 1, a distance L1 from a position where a perpendicular line drawn from one end portion of the first metal layer 15 (gate electrode) in the direction of the oxide semiconductor layer 11 intersects the oxide semiconductor layer 11 to a position where a perpendicular line drawn from the other end portion of the first metal layer 15 (gate electrode) in the direction of the oxide semiconductor layer 11 intersects the oxide semiconductor layer 11 corresponds to the gate width L.

In the present specification, the effective channel length L_{eff} refers to a width of an oxide semiconductor layer portion (hereinafter, referred to as “effective channel region”) having a carrier concentration that effectively functions as a channel region, and corresponds to L2 in FIG. 1.

The carrier concentration of the oxide semiconductor layer portion functioning as a channel may be, for example, 1×10¹⁸ cm⁻³ or less, it may be 1×10¹⁷ cm⁻³ or less, and it may be 1×10¹⁶ cm⁻³ or less.

The effective channel length L_{eff} is a value defined by L_{eff}=L1−(ΔL₁+ΔL₂). Depending on the structure of the channel region of the semiconductor device, ΔL₁ and ΔL₂ may be substantially the same value or may be different values.

As described later, each of ΔL₁ and ΔL₂ may be a positive value, 0 μm, or a negative value.

When the sum of ΔL₁+ΔL₂ is a positive value, the effective channel length L_{eff} is smaller than the gate width L₁. On the other hand, when the sum of ΔL₁+ΔL₂ is a negative value, the effective channel length L_{eff} is larger than the gate width L₁.

In the configuration illustrated in FIG. 1, the channel region 11B is located immediately below the first metal layer 15, and the impurity region 11A is formed adjacent to both sides of the channel region 11B in the horizontal direction in the drawing; however, the positional relationship between the channel region 11B and the impurity region 11A is not limited to the configuration illustrated in FIG. 1, and for example, the impurity region 11A may be formed adjacent to only one side of the channel region 11B.

In the configuration illustrated in FIG. 1, the channel region 11B and the impurity region 11A are adjacent to each other; however, the channel region 11B and the impurity region 11A do not necessarily have to be in direct contact with each other, and for example, as illustrated in FIG. 2, another region 11C may exist between the channel region 11B and the impurity region 11A.

When a plurality of impurity regions are present in the semiconductor device, the impurity region having the shortest electrical connection distance to a target channel region is defined as the impurity region 11A (boron ion measurement target).

In the following description, the target channel region means a channel region having the smallest value of channel width×channel length in the semiconductor device.

When impurity regions exist on the right and left with respect to the target channel region, a side where the amount of boron contained in the impurity region is larger (that is, a side where the volume of the impurity region is larger) may be set as the impurity region 11A (boron ion measurement target), and the other side may be set as an impurity region 11A′ (boron ion non-measurement target).

When impurity regions exist on the right and left with respect to the target channel region and there is no difference in the amount of boron contained in the right and left impurity regions, the impurity region 11A (boron ion measurement target) and the impurity region 11A′ (boron ion non-measurement target) may be arbitrarily determined.

When there are a plurality of the channel regions, a target channel region may be arbitrarily selected from the plurality of channel regions.

However, when both a structural unit A in which the channel region and the impurity region are in direct contact with each other and a structural unit B in which the channel region and the impurity region are not in direct contact with each other and another region exists between the channel region and the impurity region are present in one semiconductor device, the channel region of the structural unit A in direct contact with the impurity region is referred to as “target channel region” and the impurity region of the structural unit A in direct contact with the channel region is referred to as “impurity region 11A (boron ion measurement target)”.

In the semiconductor device of the present aspect, the linear mobility μₗᵢₙ is 15 cm²/Vs or more.

When the linear mobility μₗᵢₙ is 15 cm²/Vs or more, a high-mobility semiconductor device can be provided.

The linear mobility μₗᵢₙ is more preferably 20 cm²/Vs or more, 30 cm²/Vs or more, or 40 cm²/Vs or more.

The linear mobility of TFT is determined from a transfer characteristic when a drain voltage of 0.1 V is applied. A method for measuring the saturation mobility of the TFT will be described in detail in Examples.

In the semiconductor device of the present aspect, the threshold voltage (Vth) exceeds −2.40 V (more than −2.40 V).

When the threshold voltage (Vth) exceeds −2.40 V (more than −2.40 V), it is possible to perform correction to Vth=0 V by mounting the Vth correction circuit on the TFT. When the obtained TFT is mounted on a panel, a display can be driven without causing luminance unevenness and image sticking.

The lower limit of the threshold voltage (Vth) may be −2.3 V or more, −2.25 V or more, −2.2 V or more, −2.0 V or more, or −1.0 V or more.

The upper limit of the threshold voltage (Vth) may be 2.0 V or less, less than 1.5 V, 1.4 V or less, or 1.0 V or less.

The threshold voltage (Vth) is preferably −2.2 V or more and 2.0 V or less, more preferably −2.0 V or more and 2.0 V or less, more preferably −2.0 V or more and 1.4 V or less, and still more preferably −1.0 V or more and 1.0 V or less.

The most preferable range of the threshold voltage (Vth) is 0 or more and 1.0 or less. When the threshold voltage (Vth) is 0 V or more, a normally-off transistor can be provided even without a correction circuit.

A method for measuring the threshold voltage (Vth) of the TFT will be described in detail in Examples.

The average boron concentration of the impurity region 11A (hereinafter, simply referred to as an impurity region) may be 5×10¹⁸ cm⁻³ or more, 5×10¹⁹ cm⁻³ or more, 9×10¹⁹ cm⁻³ or more, 3×10²⁰ cm⁻³ or more, or 5×10²⁰ cm⁻³ or more, and it may be 5×10²¹ cm⁻³ or less, 3×10²¹ cm⁻³ or less, 2×10²¹ cm⁻³ or less, 1×10²¹ cm⁻³ or less, 6×10²⁰ cm⁻³ or less, 3×10²⁰ cm⁻³ or less, or 3×10¹⁹ cm⁻³ or less.

The average boron concentration of the impurity region 11A may be 5×10¹⁸ to 5×10²¹ cm⁻³, it may be 5×10¹⁸ to 3×10²¹ cm⁻³, it may be 5×10¹⁹ to 1×10²¹ cm⁻³, and it may be 1×10²⁰ to 5×10²⁰ cm⁻³.

The term “average boron concentration” means the number of boron atoms per unit volume (atoms/cm³).

A method for measuring the average boron concentration of the impurity region 11A will be described in detail in Examples.

By setting the average boron concentration of the impurity region 11A to the lower limit value or more, the resistance value of the impurity region connected to the source/drain electrodes can be set to, for example, 0.05 Ωcm or less (more preferably 0.005 Ωcm or less), which is sufficiently low-resistance region.

As the average boron concentration of the impurity region 11A is higher, the sheet resistance of the impurity region 11A is reduced, so that it is possible to suppress hindrance of the operation of the high-mobility semiconductor device electrically connected to the impurity region 11A.

By setting the average boron concentration of the impurity region 11A in the above upper limit range, the intrusion of boron ions into the channel region 11B is suppressed, and a phenomenon in which the difference between the gate width and the effective channel length increases (that is, the effective channel length L_{eff} decreases) can be suppressed.

Therefore, by setting the average boron concentration of the impurity region 11A to a predetermined region that is equal to or higher than the above-described lower limit value and equal to or lower than the above-described upper limit value, the semiconductor device exhibits favorable semiconductor characteristics, and it is possible to achieve both the effect when the average boron concentration is equal to or lower than the upper limit value and the effect when the average boron concentration is equal to or higher than the lower limit value.

The average boron concentration of the channel region 11B (hereinafter, simply referred to as the channel region) may be 5×10¹⁸ cm⁻³ or less, less than 5×10¹⁸ cm⁻³, 4×10¹⁸ cm⁻³ or less, 3×10¹⁸ cm⁻³ or less, or 1×10¹⁸ cm⁻³ or less.

Since boron combines with oxygen in the oxide semiconductor to supply carriers, by setting the average boron concentration of the channel region 11B to be the upper limit value or less, an appropriate carrier exists in the channel region, so that an electron trap is filled, and a TFT having high mobility is easily obtained.

As the average boron concentration of the channel region 11B is lower, the carrier concentration of the channel region 11B is reduced, so that the channel region 11B easily exhibits favorable on/off characteristics. Since Vth tends to be a positive value as the average boron concentration of the channel region 11B is lower, the semiconductor device exhibits favorable semiconductor characteristics.

When the average boron concentration of the channel region 11B is, for example, 5×10¹⁸ cm⁻³ or less, a particular problem hardly occurs, and the lower limit value is not particularly limited. Boron present in a trace amount in the channel region 11B is effective for controlling Vth in the positive direction as a component for filling oxygen deficiency.

The average boron concentration of the channel region 11B may be 1×10¹⁸ to 5×10¹⁸ cm⁻³, it may be 2×10¹⁸ to 5×10¹⁸ cm⁻³, it may be 2×10¹⁸ to 4×10¹⁸ cm⁻³, it may be 3×10¹⁸ to 4×10¹⁸ cm⁻³, and it may be 2×10¹⁸ to 3×10¹⁸ cm⁻³.

A method for measuring the average boron concentration of the channel region 11B will be described in detail in Examples.

The lower limit value of the average boron concentration of the channel region 11B is not particularly limited, but the average boron concentration in the oxide semiconductor may be 1×10¹⁸ cm⁻³ or more. When the average boron concentration in the oxide semiconductor is less than 1×10¹⁸ cm⁻³, there is a possibility that the concentration becomes equal to or less than the measurement lower limit value and cannot be measured. Impurity ions may be diffused from the peripheral layer of the oxide semiconductor layer 11, and the impurity concentration (for example, boron concentration) in the oxide semiconductor layer 11 may be 1×10¹⁸ cm⁻³ or more.

The specific resistance value of the impurity region 11A of the oxide semiconductor layer 11 may be 0.05 Ωcm or less, 0.03 Ωcm or less, 0.01 Ωcm or less, or 0.005 Ωcm or less.

Since the wiring resistance decreases when the specific resistance value of the impurity region 11A is the upper limit value or less, when a high-mobility TFT is connected to the impurity region 11A, a decrease in mobility of the TFT can be suppressed.

The lower limit value of the specific resistance value of the impurity region 11A is not particularly limited, and may be 0.0005 Ωcm or more or 0.001 Ωcm or more.

A method for measuring the specific resistance value of the impurity region 11A will be described in detail in Examples.

The sheet resistance value of the impurity region 11A of the oxide semiconductor layer 11 may be 7,000Ω/□ or less, 6,000Ω/□ or less, or 5,500Ω/□ or less.

When the sheet resistance value of the impurity region 11A is the upper limit value or less, it is possible to suppress the occurrence of a problem in that the characteristics of other TFT regions electrically connected to the impurity region 11A are not sufficiently exhibited.

The lower limit value of the sheet resistance value of the impurity region 11A is not particularly limited, and may be 100Ω/□ or more or 200Ω/□ or more.

A method for measuring the sheet resistance value of the impurity region 11A will be described in detail in Examples.

The specific resistance of 0.005 Ωcm for the oxide semiconductor layer having a film thickness of 10 nm means a sheet resistance of 5,000 Ω/□.

The specific resistance of 0.015 Ωcm for the oxide semiconductor layer having a film thickness of 30 nm means a sheet resistance of 5,000 Ω/□.

When the constituent material of the oxide semiconductor layer 11 is a semiconductor material having a mobility of 20 cm²/Vs or more, the sheet resistance value of the impurity region 11A may be 10,000Ω/□ or less, and it is preferably 3,333Ω/□ or less, more preferably 1,000Ω/□ or less, and still more preferably 500Ω/□ or less.

When the constituent material of the oxide semiconductor layer 11 is a semiconductor material having a mobility of 20 cm²/Vs or more and the film thickness of the oxide semiconductor layer is 30 nm, the specific resistance value of the impurity region 11A may be 0.03 Ωcm or less, and it is preferably 0.01 Ωcm or less, more preferably 0.003 Ωcm or less, and still more preferably 0.0015 Ωcm or less.

When the sheet resistance value of the impurity region 11A is the upper limit value or less, it is possible to suppress the occurrence of a problem in that the characteristics of other TFT regions electrically connected to the impurity region 11A are not sufficiently exhibited.

In addition to In, the oxide semiconductor layer may contain one or more elements selected from the group consisting of H, B, C, N, O, F, Mg, Al, Si, O, S, Cl, Ar, Ca, Sc, Ti, V, Cr, Mn, Fe, Co, Ni, Cu, Zn, Ga, Ge, Y, Zr, Nb, Mo, Tc, Ru, Rh, Pd, Ag, Cd, Sn, Sb, Cs, Ba, Ln, Hf, Ta, W, Re, Os, Ir, Pt, Au, Pb and Bi.

In the present embodiment, the oxide semiconductor layer may be substantially composed only of elements selected from In, Mg, Al, Si, Zn, Ga, Mo, Sn, Ln element (lanthanoid element), and O. Here, “substantially” means that the oxide semiconductor layer included in the semiconductor device according to the present embodiment may contain other components in a range in which the effect of the present invention caused by the combination of In, Mg, Al, Si, Zn, Ga, Mo, Sn, Ln, and O is generated.

In the present embodiment, in a more preferable first mode of the oxide semiconductor layer, the metal elements are In and Ga, and the atomic percent satisfies the following formula (11).

$$[ Ga ] / ( [ In ] + [ G a ] ) < 22 at \% \qquad ( 11 )$$

The metal element may include inevitable impurities and F or H in addition to O. With the above composition range, the amount of In increases, and Ga is substituted for the In site at an annealing temperature of about 300° C., so that crystallization into a bixbyite structure can be performed. By adding Ga having a strong bonding force with oxygen, oxygen deficiency after annealing can be suppressed, and a stable film as a semiconductor can be formed.

In the present embodiment, a more preferable second mode of the oxide semiconductor layer contains In and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb and Lu as metal elements, and satisfies the following formula (12) as an atomic percent when a metal element other than In is taken as X.

$$[ X ] / ( [ In ] + [ X ] ) < 15 at \% \qquad ( 12 )$$

The metal element may include inevitable impurities and F or H in addition to O. With the above composition range, the amount of In increases, and it is possible to crystallize into a bixbyite structure in which X is substituted for the In site at an annealing temperature of about 300° C. By adding the element X having a strong bonding force with oxygen, oxygen deficiency after annealing can be suppressed, and a stable film as a semiconductor can be formed.

In the present embodiment, a more preferable third mode of the oxide semiconductor layer contains In, Ga, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb and Lu as metal elements, and the atomic percent satisfies the following formulas (13) and (14) when a metal element other than In and Ga is taken as an additive element X.

$$[ Ga ] / ( [ In ] + [ G a ] + [ X ] ) < 22.5 at \% \qquad ( 13 )$$

$$[ X ] / ( [ In ] + [ G a ] + [ X ] ) < 8. at \% \qquad ( 14 )$$

The metal element may include inevitable impurities and F or H in addition to O.

With the above composition range, the amount of In increases, and it is possible to crystallize into a bixbyite structure in which Ga is substituted for the In site at an annealing temperature of about 300° C. By adding the additive element X having a strong bonding force with oxygen, oxygen deficiency after annealing can be further suppressed, and a stable film as a semiconductor can be formed.

In the present embodiment, a more preferable fourth mode of the oxide semiconductor layer contains In, Sn, and one or more elements X selected from B, Al, Sc, Mg, Zn, Ti, Y, Zr, Mo, Hf, W, Nb, Ta, Ge, Si, La, Ce, Pr, Nd, Sm, Dy, Ho, Er, Tm, Yb and Lu as metal elements, and the atomic percent satisfies the following formulas (15) and (16) when a metal element other than In and Sn is taken as an element X.

$$[ Sn ] / ( [ In ] + [ S n ] + [ X ] ) < 20 at \% \qquad ( 15 )$$

$$[ X ] / ( [ In ] + [ S n ] + [ X ] ) < 8. at \% \qquad ( 16 )$$

The metal element may include inevitable impurities and F or H in addition to O.

With such a composition range, the amount of In increases, and it is possible to crystallize into a bixbyite structure in which Sn is substituted for the In site even by annealing at a low temperature such as 300° C. Since Sn has a large ionic radius and has a large overlap of orbits with In, high mobility can be maintained. By adding the additive element X having a strong bonding force with oxygen, oxygen deficiency after annealing can be further suppressed, and a stable film as a semiconductor can be formed.

In the present embodiment, a more preferable fifth mode of the oxide semiconductor layer contains In, Zn, and one or more elements X selected from B, Al, Sc, Mg, Ti, Y, Zr, Mo, Hf, W, Nb, Ta, Ge, Si, La, Ce, Pr, Nd, Sm, Dy, Ho, Er, Tm, Yb and Lu as metal elements, and the atomic percent satisfies the following formulas (17) and (18) when a metal element other than In and Zn is taken as an element X.

$$[ Zn ] / ( [ In ] + [ Z n ] + [ X ] ) < 12 at \% \qquad ( 17 )$$

$$[ X ] / ( [ In ] + [ Z n ] + [ X ] ) < 8. at \% \qquad ( 18 )$$

The metal element may include inevitable impurities and F or H in addition to O.

With the above composition range, the amount of In increases, and it is possible to crystallize into a bixbyite structure in which Zn is substituted for the In site at an annealing temperature of about 300° C. by adding Zn, the film immediately after film formation can be brought into an amorphous state, and processing can be performed without residue during semiconductor patterning with an acid at the time of producing a semiconductor device such as a TFT. By adding the additive element X having a strong bonding force with oxygen, oxygen deficiency after annealing can be suppressed, and a stable film as a semiconductor can be formed.

The amount (atomic percent) of each metal element in the oxide semiconductor layer can be measured by transmission electron microscopy-energy dispersive X-ray spectroscopy (TEM-EDX) using an electron microscope.

For a metal element that cannot be detected by TEM-EDX or a metal element having insufficient detection sensitivity, time-of-flight secondary ion mass spectrometry (TOF-SIMS) or SIMS analysis using a sector-type dynamic secondary ion mass spectrometer can be used.

When it is difficult to perform measurement in the above analysis, measurement can be performed by micro X-ray photoelectron spectroscopy (μXPS) or microbeam rutherford backscattering spectrometry (μRBS).

When there is a problem in quantitative accuracy even in the analysis methods listed above, the analysis accuracy of each analysis method can be improved by combining each analysis method listed above with ICP measurement using an inductively coupled plasma emission spectrometer and a standard oxide thin film. For example, the metal element in the oxide semiconductor layer is identified by cross-sectional TEM-EDX, and the (quantitative accuracy: error range of about 10 atom %) is identified by semi-quantitative analysis. Next, using the semi-quantitative analysis result (composition ratio identified in the left) as a reference value, ten standard samples of oxide semiconductor thin films in which the composition ratio is changed are prepared. With respect to the change in the composition ratio, an arbitrary composition ratio can be selected so that the proportion of the metal element contained as the composition falls within a range of +20 atom % with the reference value as the center. Other design values such as the film thickness are preferably close to thin film information to be analyzed. For example, a metal element in the oxide semiconductor layer is identified by cross-sectional TEM-EDX, and a composition ratio is identified by semi-quantitative analysis within an error range of about 10 atom %. For the standard oxide thin film, the TEM-EDX measurement result can be calibrated using the value measured by an inductively coupled plasma emission spectrometer as the absolute value of the composition ratio. This calibration can also be applied to two types of measurement methods such as TEM-EDX and TOF-SIMS.

In one embodiment, the film thickness of the oxide semiconductor layer is preferably 100 nm or less.

When the film thickness of the oxide semiconductor layer is 100 nm or less, Vth and an off current value, which are representative parameters as TFT characteristics, can be easily controlled.

The film thickness of the oxide semiconductor layer is more preferably 80 nm or less, more preferably 50 nm or less, and still more preferably 30 nm or less.

On the other hand, the film thickness of the oxide semiconductor layer is, for example, 1 nm or more, it may be 5 nm or more, it may be 10 nm or more, and it may be 15 nm or more. By setting the film thickness of the oxide semiconductor layer to 1 nm or more, high-quality crystals can be grown without being affected by the substrate material during annealing crystallization (during film formation of the oxide semiconductor layer).

By setting the film thickness of the oxide semiconductor layer to 1 nm or more, a low sheet resistance value is easily obtained in the oxide semiconductor layer.

In the present specification, the film thickness is measured based on a cross-sectional TEM observation image (referred to as “cross-sectional TEM image” in some cases).

In FIG. 1 and FIG. 3 described later, the oxide semiconductor layer 11 is a single layer, but the semiconductor device of the present aspect is not limited to such a configuration. For example, the oxide semiconductor layer 11 may include two or more layers having a multilayer structure. In this case, the layers may be made of different materials or may be made of the same material.

In one embodiment, the oxide semiconductor layer includes crystal grains having a bixbyite structure in electron beam diffraction. Since the crystal grains having a bixbyite structure have a cubic shape with good symmetry, it is possible to suppress deterioration of TFT characteristics (mobility) even across the crystal grain boundaries.

A method for evaluating whether or not the crystal grains in the oxide semiconductor layer have a bixbyite structure will be described in detail in Examples.

### (First Insulating Layer)

In one embodiment, the first insulating layer 13 is in contact with the impurity region 11A of the oxide semiconductor layer 11, and it has a first impurity-added insulating film region 131 having a thickness d13 up to 100 nm from an interface between the impurity region and the first insulating layer (see FIG. 1).

The “thickness up to 100 nm” means a thickness of 100 nm when the film thickness of the first insulating layer is 100 nm or more, and it means the total film thickness of the first insulating layer when the film thickness of the first insulating layer is less than 100 nm.

When the first insulating layer is provided in contact with a substrate (for example, a glass substrate) functioning as an insulating layer, it means a thickness up to 100 nm in the total thickness of the first insulating layer and the substrate. When the oxide semiconductor layer is formed directly on a glass substrate functioning as an insulating layer, the glass substrate corresponds to the first insulating layer.

When the first insulating layer (the insulating film and the glass substrate) in contact with the oxide semiconductor layer is less than 100 nm, the “thickness up to 100 nm” means the total film thickness of the first insulating layer including the insulating film and the glass substrate.

The “thickness up to 100 nm” when there is a metal layer in contact with the first insulating layer (insulating film and/or glass substrate) means a thickness up to the interface between the first insulating layer and the metal layer when the thickness of the first insulating layer up to the interface with the metal layer is 100 nm or less, and it means a thickness up to 100 nm of the first insulating layer when the thickness of the first insulating layer up to the interface with the metal layer exceeds 100 nm.

The average boron concentration of the first impurity-added insulating film region 131 (hereinafter, simply referred to as the first impurity-added insulating film region) is 1×10¹⁷ to 3×10²¹ cm⁻³.

A method for measuring the average boron concentration of the first impurity-added insulating film region will be described in detail in Examples.

The average boron concentration of the first impurity-added insulating film region 131 may be 1×10¹⁷ cm⁻³ or more, 1×10¹⁸ cm⁻³ or more, 1×10¹⁹ cm⁻³ or more, 1×10²⁰ cm⁻³ or more, or 1×10²¹ cm⁻³ or more, and it may be 3×10²¹ cm⁻³ or less, 3×10²⁰ cm⁻³ or less, 3×10¹⁹ cm⁻³ or less, or 3×10¹⁸ or less.

The average boron concentration of the first impurity-added insulating film region 131 may be 1×10¹⁸ to 3×10²¹ cm⁻³, it may be 1×10¹⁹ to 3×10²¹ cm⁻³, it may be 1×10¹⁹ to 3×10²⁰ cm⁻³, it may be 3×10¹⁹ to 3×10²⁰ cm⁻³, and it may be 1×10²⁰ to 3×10²⁰ cm⁻³.

By setting the average boron concentration of the first impurity-added insulating film region to the lower limit value or more, the resistance of the impurity region 11A can be reduced.

By setting the average boron concentration of the first impurity-added insulating film region to the upper limit value or less, the total amount of boron to be ion-implanted can be reduced, which is advantageous for shortening the treatment time. When an excessive amount of boron is implanted, the implanted boron serves as a scattering source, and there is a possibility that a problem such as an increase in resistance of the impurity region 11A occurs; however, by setting the average boron concentration of the first impurity-added insulating film region to the upper limit value or less, the occurrence of such a problem can be suppressed.

By setting the average boron concentration of the first impurity-added insulating film region 131 to a predetermined region that is equal to or higher than the above-described lower limit value and equal to or lower than the above-described upper limit value, it is possible to achieve both the effect when the average boron concentration is equal to or lower than the upper limit value and the effect when the average boron concentration is equal to or higher than the lower limit value.

A method for measuring the average boron concentration of the first impurity-added insulating film region will be described in detail in Examples.

### (Material of First Insulating Layer)

A material for forming the first insulating layer is not particularly limited, and a generally used material can be arbitrarily selected, and a stacked film can be used. For example, SiO₂, SiNx, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, SC₂O₃, Y₂O₃, HfO₂, CaHfO₃, PbTiO₃, BaTa₂O₆, SrTiO₃, Sm₂O₃, or AlN can be used. The oxidation number of each material may vary. The first insulating layer can be appropriately designed according to the type of the substrate.

When the first insulating layer is an insulating substrate, the substrate can be regarded as the first insulating layer. The first insulating layer extends in the direction perpendicular to the substrate surface up to a region where the metal layer or the semiconductor layer appears on the lower layer side when the interface side with the oxide semiconductor layer is defined as the upper layer side. Since the metal layer or the semiconductor layer on the lower layer side is patterned in the substrate in-plane direction, the first insulating layer is limited to a region up to the interface with the lower insulating layer when the lower insulating layer and the first insulating layer present on the lower layer side are in contact with each other.

The film thickness of the first insulating layer is, for example, 10 nm or more, it may be 50 nm or more, it may be 100 nm or more, it may be 300 nm or more, and it may be 500 nm or more.

By setting the film thickness of the first insulating layer to 10 nm or more, it is easy to secure an insulating state between the metal film or the semiconductor layer existing on the lower layer side and the oxide semiconductor layer.

The upper limit of the film thickness of the first insulating layer is not particularly limited, and it is, for example, 1,000 nm or less, it may be 500 nm or less, it may be 200 nm or less, and it may be 50 nm or less.

When the film thickness of the first insulating layer is 1,000 nm or less, a stable device shape can be obtained in the semiconductor device of the present embodiment.

The upper limit of the film thickness of the first insulating layer when the first insulating layer is an insulating substrate or when the first insulating layer includes an insulating substrate is not particularly limited, and is generally 1,000 nm or less.

By setting the film thickness of the first insulating layer to a predetermined region that is equal to or higher than the above-described lower limit value and equal to or lower than the above-described upper limit value, it is possible to achieve both the effect when the film thickness is equal to or lower than the upper limit value and the effect when the film thickness is equal to or higher than the lower limit value.

The first insulating layer may be a single-layer film, and it may be a stacked film. In the case of a stacked film, the preferable film thickness described for the first insulating layer is the film thickness of the entire stacked film.

### (Second Insulating Layer)

In one embodiment, the second insulating layer 14 is an insulating layer that is formed in the same process as the gate insulating film (a gate insulating film region 142 in FIG. 1) present at a position overlapping the channel region 11B of the oxide semiconductor layer and is in contact with the impurity region 11A in the perpendicular direction.

In one embodiment, the second insulating layer 14 is in contact with the impurity region 11A on a surface of the oxide semiconductor layer 11 on a side opposite to a contact surface with the first insulating layer 13.

The second insulating layer 14 is basically composed of the same constituent element as the gate insulating film (the gate insulating film region 142 in FIG. 1) and has the same layer configuration, but the diffusion degree of impurity components (for example, boron ions) may be different between a region in contact with the impurity region and a region in contact with the channel region.

When the gate insulating film (the gate insulating film region 142 in FIG. 1) is partially etched, the gate insulating film (the gate insulating film region 142 in FIG. 1) and the second insulating layer 14 may have different film thicknesses, and the second insulating layer 14 may be discontinuous with the channel region in the substrate in-plane direction. However, the second insulating layer 14 shares a part of the configuration of the layer formed in the same process (for example, the gate insulating film region 142 of the second insulating layer 14).

In one embodiment, the second insulating layer 14 has a second impurity-added insulating film region 141, and the average boron concentration of the second impurity-added insulating film region 141 is 5×10¹⁸ to 5×10²¹ cm⁻³.

A method for measuring the average boron concentration of the second impurity-added insulating film region 141 of the second insulating layer will be described in detail in Examples.

The average boron concentration of the second impurity-added insulating film region 141 of the second insulating layer 14 may be 5×10¹⁸ cm⁻³ or more, 1×10¹⁹ cm⁻³ or more, 5×10¹⁹ cm⁻³ or more, or 5×10²⁰ cm⁻³ or more, and it may be 5×10²¹ cm⁻³ or less, 5×10²⁰ cm⁻³ or less, or 5×10¹⁹ cm⁻³ or less.

The average boron concentration of the second impurity-added insulating film region may be 5×10¹⁹ to 5×10²¹ cm⁻³, and it may be 5×10¹⁹ to 5×10²⁰ cm⁻³.

By setting the average boron concentration of the second impurity-added insulating film region to the lower limit value or more, boron diffusion from the impurity region 11A to the second impurity-added insulating film region can be suppressed, so that more stable resistance characteristics can be obtained in the impurity region 11A.

By setting the average boron concentration of the second impurity-added insulating film region to the upper limit value or less, boron diffusion from the second impurity-added insulating film region to the impurity region 11A can be suppressed, so that more stable resistance characteristics can be obtained in the impurity region 11A.

By setting the average boron concentration of the second impurity-added insulating film region to a predetermined region that is equal to or higher than the above-described lower limit value and equal to or lower than the above-described upper limit value, it is possible to achieve both the effect when the average boron concentration is equal to or lower than the upper limit value and the effect when the average boron concentration is equal to or higher than the lower limit value.

### (Material of Second Insulating Layer)

A material for forming the second insulating layer is not particularly limited, and a generally used material can be arbitrarily selected, and a stacked film can be used. For example, SiO₂, SiNx, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN can be used. The oxidation number of each material may vary.

The film thickness of the second insulating layer is, for example, 10 nm or more, it may be 50 nm or more, it may be 100 nm or more, it may be 200 nm or more, and it may be 300 nm or more.

By setting the film thickness of the second insulating layer to 10 nm or more, the ion implantation process can be performed while suppressing exposure of the oxide semiconductor surface to the atmosphere in the indirect-implantation-type ion implantation process described in a production step of the semiconductor device described later, so that the oxide semiconductor layer including the impurity region 11A and the channel region 11B having the average boron concentrations described above can be stably obtained.

The upper limit of the film thickness of the second insulating layer is not particularly limited, and it is, for example, 300 nm or less, it may be 200 nm or less, it may be 150 nm or less, and it may be 100 nm or less.

When the film thickness of the second insulating layer is 300 nm or less, a stable device shape can be obtained in the semiconductor device of the present embodiment.

The second insulating layer may be a single-layer film, and it may be a stacked film. In the case of a stacked film, the preferable film thickness described for the second insulating layer is the film thickness of the entire stacked film.

In one embodiment, the second insulating layer 14 having the second impurity-added insulating film region 141 has the gate insulating film region 142.

The gate insulating film region 142 is a region functioning as a gate insulating film. For example, in the example illustrated in FIG. 1, a region immediately below the first metal layer 15 in the second insulating layer 14 is a region functioning as a gate insulating film.

In one embodiment, the gate insulating film region 142 in the second insulating layer 14 has an average boron concentration of 1×10¹⁷ to 5×10²⁰ cm⁻³.

A method for measuring the average boron concentration of the gate insulating film region 142 will be described in detail in Examples.

The average boron concentration of the gate insulating film region 142 may be 1×10¹⁷ cm⁻³ or more, 1×10¹⁸ cm⁻³ or more, 1×10¹⁹ cm⁻³ or more, or 1×10²⁰ cm⁻³ or more, and it may be 5×10²⁰ cm⁻³ or less, 5×10¹⁹ cm⁻³ or less, or 5×10¹⁸ cm⁻³ or less.

The average boron concentration of the gate insulating film region 142 may be 1×10¹⁸ to 5×10²⁰ cm⁻³, it may be 1×10¹⁸ to 5×10¹⁹ cm⁻³, and it may be 5×10¹⁸ to 5×10¹⁹ cm⁻³.

By setting the average boron concentration of the gate insulating film region 142 to the lower limit value or more, boron impurity-implanted into the second impurity-added insulating film region has an appropriate concentration gradient continuously with the gate insulating film region, so that a stable semiconductor device with less boron diffusion between the insulating films (between the second impurity-added insulating film region of the second insulating layer and the gate insulating film region thereof) can be supplied.

By setting the average boron concentration of the gate insulating film region 142 to the upper limit value or less, a gate insulating film excellent in withstand voltage can be provided.

By setting the average boron concentration of the second insulating layer to a predetermined region that is equal to or higher than the above-described lower limit value and equal to or lower than the above-described upper limit value, it is possible to achieve both the effect when the average boron concentration is equal to or lower than the upper limit value and the effect when the average boron concentration is equal to or higher than the lower limit value.

### Second Embodiment

Hereinafter, a semiconductor device according to a second embodiment of the present aspect will be described.

FIG. 3 is a schematic cross-sectional view for explaining a configuration example of a semiconductor device according to a second embodiment of the present aspect.

A semiconductor device 200 includes, on a substrate 12, a first insulating layer 13, an oxide semiconductor layer 11 stacked in contact with the first insulating layer 13 and having an impurity region 11A and a channel region 11B, and a second insulating layer 16 in contact with the channel region 11B of the oxide semiconductor layer 11 in a direction perpendicular to the plane on a side opposite to a contact surface with the first insulating layer 13 of the oxide semiconductor layer 11, wherein a first metal layer 15 is stacked on the second insulating layer 16, and the second insulating layer 16 and the first metal layer 15 have substantially the same width as the channel region 11B.

A second metal layer and a third metal layer (not illustrated) directly connected to the impurity region 11A of the oxide semiconductor layer 11 are provided.

The semiconductor device illustrated in FIG. 3 is different from the semiconductor device illustrated in FIG. 1 in that the second impurity-added insulating film region is not provided on the impurity-added region 11A.

In the semiconductor device illustrated in FIG. 3, since there is no second impurity-added insulating film region, a mode is illustrated in which the second and third metal layers (not illustrated) can be directly connected to the impurity region 11A of the oxide semiconductor layer 11; however, the semiconductor device according to the second embodiment is not necessarily limited to such a mode, and the second metal layer and the third metal layer may be connected to the impurity region 11A of the oxide semiconductor layer 11 via a contact hole formed in the insulating layer.

### (2ΔL: Difference Between Gate Width L and Effective Channel Length L_{eff})

In one embodiment of the semiconductor device (first embodiment and second embodiment) of the present aspect, a difference (ΔL₁+ΔL₂) between the gate width L (L₁ in FIGS. 1 and 3) and the effective channel length L_{eff} (L₂ in FIGS. 1 and 3) is defined as 2ΔL. Therefore, ΔL is (ΔL₁+ΔL₂)/2 in FIGS. 1 and 3.

The difference 2ΔL between the gate width L and the effective channel length L_{eff} (difference between L₁ and L₂ in FIGS. 1 and 3) is 3.4 μm or less, preferably 2.2 μm or less, and more preferably 2.0 μm or less.

In the semiconductor device of the present aspect, boron implanted into the impurity region 11A of the oxide semiconductor layer 11 is less likely to enter the channel region 11B side from the impurity region 11A, so that the difference between the gate width L and the effective channel length L_{eff} can be reduced.

In one embodiment of the semiconductor device (first embodiment and second embodiment) of the present aspect, one or both of ΔL₁ and ΔL₂ represented by the following formulas are preferably 1.1 μm or less, preferably 1.0 μm or less, preferably 0.9 μm or less, preferably 0.8 μm or less, and more preferably 0.7 μm or less:

$${L}_{eff} = L - ( Δ {L}_{1} + Δ {L}_{2} )$$

wherein in the formula, L_{eff} is an effective channel length (L₂ in FIGS. 1 and 3) in the channel region, L is a width of a gate electrode in a source electrode-drain electrode direction (L₁ in FIGS. 1 and 3), ΔL₁ is a distance from a position where a perpendicular line drawn from one end portion of the gate electrode 15 in a direction of the oxide semiconductor layer 11 intersects the oxide semiconductor layer 11 to an end portion of a region (effective channel region) having a carrier concentration that functions as a channel in the oxide semiconductor layer 11, ΔL₂ is a distance from a position where a perpendicular line drawn from the other end portion of the gate electrode 15 in the direction of the oxide semiconductor layer 11 intersects the oxide semiconductor layer 11 to an end portion of a region (effective channel region) having a carrier concentration that functions as a channel in the oxide semiconductor layer 11.

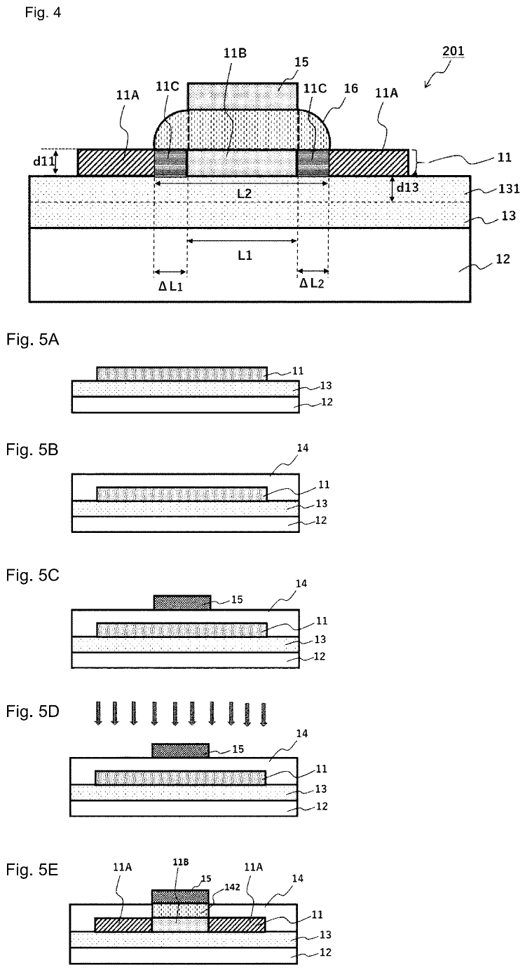

FIGS. 1 and 3 illustrate an example in which both ΔL₁ and ΔL₂ are positive values, but ΔL₁ and ΔL₂ may be negative values. As an example in which ΔL₁ and ΔL₂ may be negative values, for example, a semiconductor device having a structure illustrated in FIG. 4 is mentioned. One of ΔL₁ and ΔL₂ may be a positive value, and the other may be a negative value.

The value of ΔL can be calculated or measured by the method described in Examples.

FIG. 4 is a schematic cross-sectional view for explaining another configuration example of the semiconductor device according to the second embodiment of the present aspect.

In a semiconductor device 201 illustrated in FIG. 4, the second insulating layer 16 provided between the oxide semiconductor layer 11 and the first metal layer 15 is slightly wider than the first metal layer 15, and the side end portion of the second insulating layer 16 protrudes outward from the end surface of the first metal layer 15.

The oxide semiconductor layer 11 of the semiconductor device 201 includes a channel region 11B formed in a region overlapping the first metal layer 15 in a region in contact with the second insulating layer 16, a region 11C formed in a region in contact with the second insulating layer 16 protruding outward from the end surface of the first metal layer 15 (a region excluding the channel region 11B in a region in contact with the second insulating layer 16), and an impurity region 11A formed adjacent to the region 11C in a region not in contact with the second insulating layer 16.

The amount of the boron in the region 11C is larger than the amount of the boron in the channel region 11B, and it is smaller than the amount of the boron in the impurity region 11A.

The basic configuration of the semiconductor device 201 illustrated in FIG. 4 is similar to that of the semiconductor device 200 illustrated in FIG. 3 except for the points described above.

In the semiconductor device 201 illustrated in FIG. 4, L2 corresponding to the effective channel length L_{eff} may be the total width of the channel region 11B and the region 11C on both sides, and in this case, a value of (ΔL₁+ΔL₂), which is a difference (L1−L2) between the gate width L1 and the effective channel length L2, is a negative value.

### 2. Method for Producing Semiconductor Device

### (Method for Producing Semiconductor Device of First Embodiment: Indirect Implantation)

The semiconductor device according to the first embodiment can be produced as follows, for example: an oxide thin film containing an oxide of In as a main component is formed on a lower layer or the like constituting the semiconductor device, such as a substrate, a buffer layer and an insulating layer, then the oxide thin film is patterned in a desired shape by using photolithography, and then annealing is performed as necessary to perform a crystallization treatment, thereby forming an oxide semiconductor layer in which the atomic percent of In is 70 atom % or more based on all metal elements (oxide semiconductor layer forming step); a second insulating layer covering the entire oxide semiconductor layer is formed (second insulating film forming step); a metal layer is further formed on a part of the second insulating layer (metal layer forming step); and then, the metal layer is patterned in a desired shape by using photolithography, and boron ions are irradiated toward the second insulating layer and the metal layer (ion implantation processing step).

In the method for producing the semiconductor device according to the first embodiment, boron ions are implanted into a portion of the second insulating layer not overlapping the metal layer (ion implantation processing step), thereby forming a second impurity-added insulating film region. Boron ions diffuse from the second impurity-added insulating film region to a portion of the oxide semiconductor layer not overlapping the metal layer, and an impurity region is formed. That is, boron ions are indirectly implanted into a part of the oxide semiconductor layer via the second insulating layer, thereby forming an impurity region in a part of the oxide semiconductor layer. The portion of the oxide semiconductor layer overlapping the metal layer forms a channel region.

Hereinafter, each step of the method for producing the semiconductor device according to the first embodiment illustrated in FIG. 1 will be described with reference to FIGS. 5A-5E.

The semiconductor device according to the first embodiment can be produced as follows, for example: an oxide thin film containing an oxide of In as a main component is formed on a lower layer or the like constituting, for example, a substrate, a buffer layer, an insulating layer and the like, annealing is performed as necessary to perform a crystallization treatment, thereby forming an oxide semiconductor layer in which the atomic percent of In is 70 atom % or more based on all metal elements (oxide semiconductor layer forming step); a second insulating layer in contact with the oxide semiconductor layer is formed (second insulating layer forming step); a metal layer is formed on the second insulating layer on the oxide semiconductor layer (metal layer forming step); and boron ions are irradiated toward the oxide semiconductor layer and the metal layer (ion implantation processing step).

In the method for producing the semiconductor device according to the first embodiment, the indirect-implantation-type ion implantation of implanting boron ions into the oxide semiconductor layer via the second insulating layer is performed to form an impurity region and a channel region in the oxide semiconductor layer.

In the steps illustrated in FIGS. 5A-5E, the oxide semiconductor layer 11 is formed on the first insulating layer 13 formed on the substrate 12 (FIG. 5A).

### First Insulating Layer Forming Step

### (Film Formation of First Insulating Layer)

The film formation method for the first insulating layer is not particularly limited. Examples of the formation method include PE-CVD, ALD, PLD, MO-CVD, RF sputtering, ICP sputtering, reactive sputtering, ICP-CVD, ion plating, a sol-gel method, a coating method, mist CVD, and the like. Tetraethoxysilane (TEOS) can also be used as a gas species of PE-CVD in addition to silane (SiH₄).

When the sputtering method is employed, the atomic composition ratio of the first insulating layer obtained by the sputtering method reflects the atomic composition ratio of the oxide sintered body in the sputtering target. Therefore, it is preferable to form a film using a sputtering target including an oxide sintered body having an atomic composition ratio similar to the desired atomic composition ratio of the first insulating layer.

As the sputtering gas, it is preferable to use, as the sputtering gas, one or more gases selected from the group consisting of argon and oxygen that are substantially free of impurity gases, as in the film formation of an oxide thin film described later.

Each of the amount of the impurity gas in the sputtering gas, the preferred range of the purity of argon in the sputtering gas, and the preferred range of purity of oxygen in the sputtering gas is the same as the preferred range in the film formation of an oxide thin film described later.

The gas (sputtering gas) introduced at the time of sputtering film formation is not particularly limited, and examples thereof include argon, nitrogen, oxygen, water, hydrogen, or a mixed gas containing two or more of these gases.

### (Heat Treatment of First Insulating Layer)

After the film formation of the first insulating layer, a heat treatment (annealing treatment) may be performed.

### Oxide Semiconductor Layer Forming Step

### (Film Formation of Oxide Thin Film)

A film formation method for the oxide thin film having an In-containing amount of 70 atom % or more is not particularly limited, and examples thereof include DC sputtering, AC sputtering, RF sputtering, ICP sputtering, reactive sputtering, ion plating, ALD, PLD, MO-CVD, ICP-CVD, a sol-gel method, a coating method, and mist CVD.

When film formation is performed by sputtering, film formation may be performed by a planar sputtering cathode apparatus, or film formation may be performed by a rotary sputtering cathode apparatus.

An example of the film formation method for the oxide thin film is DC sputtering using a sputtering target including an oxide sintered body in which the atomic percent of In is 70 atom % or more based on all metal elements.

The atomic composition ratio of the oxide thin film obtained by the sputtering method reflects the atomic composition ratio of the oxide sintered body in the sputtering target. Therefore, it is preferable to form a film using a sputtering target including an oxide sintered body having an atomic composition ratio similar to the desired atomic composition ratio of the oxide thin film.

In the target used in the sputtering method, the amount of the impurity metal is preferably 500 ppm or less, and more preferably 100 ppm or less. Similarly to the oxide semiconductor layer, the amount of the impurity metal in the target can be measured by ICP or SIMS. The “impurity” contained in the target means a trace element that is not intentionally added, mixed in raw materials or in a production process, and does not substantially affect performance of the target and the semiconductor, and the “impurity metal” means a metal element among elements as “impurity”.

In the present embodiment, the sputtering target may be substantially composed only of In and elements selected from Mg, Al, Si, Zn, Ga, Mo, Sn, Ln element (lanthanoid element), and O. Here, “substantially” means that the sputtering target may contain other components in a range in which the effect of the present invention caused by the combination of In and any of Mg, Al, Si, Zn, Ga, Mo, Sn, Ln, and O is generated. Indium oxide composed of In and oxygen may be used.

Similarly to the oxide semiconductor layer included in the semiconductor device of the present invention described above, in the present embodiment, a more preferable first mode of the sputtering target is an oxide in which metal elements are In and Ga, and the atomic percent satisfies the following formula (11).

$$[ Ga ] / ( [ In ] + [ G a ] ) < 22 at \% \qquad ( 11 )$$

A more preferable second mode of the sputtering target is an oxide containing In and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb and Lu as metal elements, and satisfies the following formula (12) as an atomic percent when a metal element other than In is taken as X.

$$[ X ] / ( [ In ] + [ X ] ) < 15 at \% \qquad ( 12 )$$

A more preferable third mode of the sputtering target is an oxide containing In, Ga, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb and Lu as metal elements, and the atomic percent satisfies the following formulas (13) and (14) when a metal element other than In and Ga is taken as an additive element X.

$$[ Ga ] / ( [ In ] + [ G a ] + [ X ] ) < 22.5 at \% \qquad ( 13 )$$

$$[ X ] / ( [ In ] + [ G a ] + [ X ] ) < 8. at \% \qquad ( 14 )$$

A more preferable fourth mode of the sputtering target is an oxide containing In, Sn, and one or more elements X selected from B, Al, Sc, Mg, Zn, Ti, Y, Zr, Mo, Hf, W, Nb, Ta, Ge, Si, La, Ce, Pr, Nd, Sm, Dy, Ho, Er, Tm, Yb and Lu as metal elements, and the atomic percent satisfies the following formulas (15) and (16) when a metal element other than In and Sn is taken as an element X.

$$[ Sn ] / ( [ In ] + [ S n ] + [ X ] ) < 20 at \% \qquad ( 15 )$$

$$[ X ] / ( [ In ] + [ S n ] + [ X ] ) < 8. at \% \qquad ( 16 )$$

A more preferable fifth mode of the sputtering target is an oxide containing In, Zn, and one or more elements X selected from B, Al, Sc, Mg, Ti, Y, Zr, Mo, Hf, W, Nb, Ta, Ge, Si, La, Ce, Pr, Nd, Sm, Dy, Ho, Er, Tm, Yb and Lu as metal elements, and the atomic percent satisfies the following formulas (17) and (18) when a metal element other than In and Zn is taken as an element X.

$$[ Zn ] / ( [ In ] + [ Z n ] + [ X ] ) < 12 at \% \qquad ( 17 )$$

$$[ X ] / ( [ In ] + [ Z n ] + [ X ] ) < 8. at \% \qquad ( 18 )$$

The oxide thin film obtained by forming a film by sputtering using a sputtering target containing indium oxide as a main component may be an amorphous oxide thin film.

An amorphous oxide thin film is patterned in an island shape by photolithography, and heated to be crystallized before a protective film is formed, whereby an oxide semiconductor layer having a crystallized oxide semiconductor can be obtained.

Sputtering is preferably performed using, as the sputtering gas, one or more gases selected from the group consisting of argon and oxygen that are substantially free of impurity gases. In this step, the sputtering target is preferably mounted on an RF magnetron sputtering device or a DC magnetron sputtering device to perform sputtering.

The fact that the sputtering gas “is substantially free of impurity gases” means that impurity gases other than the sputtering gas are not actively charged, except for adsorbed water brought with gas insertion, and gases (inevitable impurity gases) which are difficult to be removed from being brought into the sputtering gas, such as leakage of the chamber and the adsorbed gas. If possible, the impurities are preferably removed from the gas (sputtering gas) introduced at the time of sputtering film formation.

The amount of the impurity gas in the sputtering gas is preferably 0.1 vol % or less, and more preferably 0.05 vol % or less. When the amount of the impurity gas is 0.1 vol % or less, crystallization of the oxide thin film proceeds without problems.

The purity of high purity argon and high purity oxygen as an example of the sputtering gas is preferably 99 vol % or more, more preferably 99.9 vol % or more, and still more preferably 99.99 vol % or more.

The gas (sputtering gas) introduced at the time of sputtering film formation is not particularly limited, and examples thereof include argon, nitrogen, oxygen, water, hydrogen, or a mixed gas containing two or more of these gases.

As an example, when argon and oxygen are used, the oxygen partial pressure in the mixed gas is preferably more than 0 vol % and 50 vol % or less, and more preferably more than 0 vol % and 20 vol % or less. When the oxygen partial pressure is more than 0 vol % and 50 vol % or less, crystallization and semiconducting are easily performed during heating. By changing the oxygen partial pressure, the oxidation degree, that is, the crystallization degree of the oxide thin film can be adjusted. The oxygen partial pressure may be appropriately selected as necessary.

As an example, when argon and water are used, the water partial pressure in the mixed gas is preferably more than 0.03 vol % and 10 vol % or less, and more preferably more than 0.03 vol % and 5 vol % or less. When the water partial pressure is more than 0.03 vol % and 5 vol % or less, crystallization and semiconducting are easily performed during heating. A mixed gas of hydrogen and oxygen may be used instead of water.

### (Heat Treatment of Oxide Thin Film)

After the oxide thin film is formed, a heat treatment may be performed before the ion implantation process. This heat treatment may be referred to as annealing. By performing the heat treatment, the oxide thin film is crystallized to form an oxide semiconductor layer.

The step of the heat treatment is not particularly limited, and a hot air furnace, an IR furnace, a lamp annealing apparatus, a laser annealing apparatus, a thermal plasma apparatus, or the like can be used.

After annealing, a plasma oxidation treatment with N₂O or a plasma oxidation treatment with O₂ may be further performed before the ion implantation process. The apparatus for the plasma oxidation treatment is not particularly limited, and examples thereof include PE-CVD and the like.

Crystal growth (for example, crystals extending in a columnar shape with respect to the lower layer) can be performed by heating the oxide thin film obtained by the sputtering film formation in the heat treatment step. By applying the oxide semiconductor layer formed as described above to the small TFT, the injection property of the electron carrier is excellent during driving, and as a result, high mobility is exhibited.

The temperature of the heat treatment of the oxide thin film is preferably 250° C. or higher and 500° C. or lower, more preferably 280° C. or higher and 470° C. or lower, and still more preferably 300° C. or higher and 450° C. or lower.

When the heat treatment temperature after the film formation of the oxide thin film is 250° C. or higher, the oxide thin film is easily crystallized. When the heat treatment temperature after the film formation of the oxide thin film is 500° C. or lower, it is possible to prevent the crystal from abnormally growing and increasing the crystal grains, and to control the crystal grain size to be small.

The heating time in the heat treatment step of the oxide thin film is preferably 0.1 hours or more and 5 hours or less, more preferably 0.3 hours or more and 3 hours or less, and still more preferably 0.5 hours or more and 2 hours or less.

When the heating time in the heat treatment step is 0.1 hours or more, a region where crystallization is insufficient is less likely to be formed, and the crystallinity of the oxide thin film tends to be high.

When the heating time in the heat treatment step is 5 hours or less, economic efficiency is excellent.

The “heating time” refers to a time (holding time) during which a predetermined maximum temperature is maintained during the heat treatment.

The temperature increase rate in the heat treatment step of the oxide thin film is preferably 2° C./min or more and 40° C./min or less, and more preferably 3° C./min or more and 20° C./min or less.

When the temperature increase rate in the heat treatment step of the oxide thin film is 2° C./min or more, the production efficiency of the oxide thin film is improved as compared with a case where the temperature increase rate is less than 1° C./min.

When the temperature increase rate in the heat treatment step of the oxide thin film is 40° C./min or less, the metal element is uniformly diffused during crystallization, and a crystal in which the metal is not segregated at the grain boundary can be formed.

The temperature increase rate in the heat treatment step is different from a value calculated from the set temperature and the set time of the furnace, and is a value obtained by dividing the actual temperature of the oxide thin film by time. The actual temperature of the oxide thin film can be determined, for example, by measuring an area within 1 cm from the oxide thin film in the furnace with a thermocouple.

The heat treatment step of the oxide thin film is preferably performed in an air atmosphere having a humidity of 10% or more at 25° C. When the humidity in the heat treatment step is 10% or more in the air, hydrogen and oxygen diffuse into the film during annealing, and crystallization can be promoted.

The heat treatment step of the oxide thin film is preferably performed after patterning of the oxide thin film. By performing the heat treatment step after patterning, crystallization can be promoted while removing excessive oxygen present in the film at the time of film formation and organic substances attached at the time of patterning. As a result, it is possible to form a film having no organic substance or excessive oxygen in the crystal grains and less crystal defects, and it is possible to form an oxide thin film having less electron traps and favorable conductivity characteristics.

The crystal defects of the film after the heat treatment step of the oxide thin film can be evaluated by, for example, defect analysis such as cathodoluminescence (CL). When there are many defects derived from oxygen, emission of light of 680 nm is strongly detected. In order to obtain an oxide thin film with less electron traps and favorable conductivity characteristics, it is necessary to adjust a film formation method and annealing conditions so as to obtain a film quality in which light emission by CL is not detected as much as possible.

The heat treatment step of the oxide thin film may be performed a plurality of times.

For example, the above-described heat treatment step (first heat treatment step) may be performed after patterning of the oxide thin film, and further, the heat treatment step (second heat treatment step) may be performed after formation of the gate insulating film to produce a TFT device, and then the heat treatment step (third heat treatment step) may be performed as a final step. The third heat treatment step is preferably performed at an annealing temperature lower than that of the first heat treatment step.

### Second Insulating Layer Forming Step

The second insulating layer 14 is formed on the surface of the oxide semiconductor layer 11 (FIG. 5B). The second insulating layer 14 is a layer having a region that functions as a gate insulating film in a semiconductor device to be finally obtained.

### (Film Formation of Second Insulating Layer)

The film formation of the second insulating layer can be performed by a method similar to that described in the first insulating layer.

### (Heat Treatment of Second Insulating Layer)

After the film formation of the second insulating layer, a heat treatment (annealing treatment) may be performed.

The temperature of the heat treatment after formation of the second insulating layer is not particularly limited. It may be, for example, 200 to 500° C., and it may be 300 to 400° C.

The heating time in the heat treatment step after formation of the second insulating layer is not particularly limited. It may be, for example, 0.1 to 5 hours, and it may be 0.5 to 1 hour.

The temperature increase rate in the heat treatment step after formation of the second insulating layer is preferably 2° C./min or more and 40° C./min or less, and more preferably 3° C./min or more and 20° C./min or less.

A method of determining the temperature increase rate in the heat treatment step after formation of the second insulating layer is the same as the method of determining the temperature increase rate in the heat treatment step of the oxide film described above.

The heat treatment step after formation of the second insulating layer is preferably performed in an air atmosphere having a humidity of 10% or more at 25° C.

### First Metal Layer Forming Step

The first metal layer 15 is formed on a part of the surface of the second insulating layer 14 (FIG. 5C).

The first metal layer can be formed in a shape covering only a part of the second insulating layer 14 by, for example, forming a layer made of a metal such as Al, Ag, Cu, Cr, Ni, Co, Mo, Au, Ti, Zr, Ru, Y, Nb, Ta and W, or an alloy containing two or more of these metals on the entire surface of the second insulating layer by, for example, a method such as sputtering, and then performing patterning by a method such as photolithography.

By forming the first metal layer 15 by patterning, a region where the second insulating layer 14 and a part of the oxide semiconductor layer 11 overlap (cover only a part of) the first metal layer 15 is formed.

### Ion Implantation Processing Step

As illustrated in FIG. 5D, boron ions are irradiated toward the second insulating layer 14 and the first metal layer 15. As a result, the first metal layer 15 serves as a mask, and boron ions are implanted into a region of the second insulating layer 14 not covered with the first metal layer 15. Boron ions are implanted into a region of the oxide semiconductor layer 11 not covered with the first metal layer 15 via the second insulating layer 14. On the other hand, implantation of boron ions into a region of the oxide semiconductor layer 11 covered with the first metal layer 15 is suppressed.

As a result, the impurity region 11A having a predetermined average boron concentration is formed in a region of the oxide semiconductor layer 11 not mainly covered with the first metal layer 15, and the channel region 11B is formed in a region of the oxide semiconductor layer 11 mainly covered with the first metal layer 15 (FIG. 5E).

Implantation of boron ions can be performed, for example, by mass-separating boron ions from an ion source (gas source) such as BF₃ gas and irradiating the boron ions. As the ion source, for example, a gaseous ion source such as BF₃ gas and BH₃ gas may be used, or solid boron may be used. The ion source is preferably BF₃ gas. In the case of performing irradiation of boron ions using BF₃ gas as an ion source, a trace amount of fluorine (F) may be mixed into an irradiated body (for example, the second insulating layer).

Some of the boron ions with which the surface of the second insulating layer 14 is irradiated at the time of the ion implantation process are implanted into the oxide semiconductor layer 11 to form the impurity region 11A, but some of the boron ions remain in the second insulating layer 14 to form the second impurity-added insulating film region 141 (see FIG. 1).

Some of the boron ions with which the surface of the second insulating layer 14 is irradiated at the time of the ion implantation process and implanted into the impurity region 11A of the oxide semiconductor layer 11 can diffuse into the channel region 11B of the oxide semiconductor layer 11 and the region functioning as the gate insulating film 142 of the second insulating layer 14 at the time of the ion implantation process or at the time of the heat treatment described later. Some of the boron ions implanted into the impurity region 11A at the time of the ion implantation process or at the time of the heat treatment described later diffuse into the first insulating layer 13, and the first impurity-added insulating film region 131 (see FIG. 1) can be formed.

In the indirect-implantation-type ion implantation process, the dose amount of boron ions may be 0.05×10¹⁵ ions/cm² or more, 0.1×10¹⁵ ions/cm² or more, 0.2×10¹⁵ ions/cm² or more, or 0.3×10¹⁵ ions/cm² or more, and it may be 8.0×10¹⁵ ions/cm² or less, 6.0×10¹⁵ ions/cm² or less, or 4.0×10¹⁵ ions/cm² or less.

By setting the dose amount of boron ions in the indirect-implantation-type ion implantation process within the above range, an impurity region can be formed in the oxide semiconductor layer 11 in a state of having an appropriate resistance value.

The beam energy of the indirect-implantation-type ion implantation process may be 0.1 keV to 1,000 keV, it may be 1 keV to 500 keV, and it may be 5 keV to 100 keV.

Suitable beam energy for the indirect-implantation-type ion implantation process can be determined according to, for example, the material and film thickness for forming the second insulating layer, the material and film thickness for forming the impurity region 11A of the oxide semiconductor layer 11, and the relationship with the ion implantation species.

For example, it is possible to calculate suitable beam energy using TRIM which is software capable of simulating the ion implantation process by the Monte Carlo method.

Specifically, when the material for forming the second insulating layer is SiO₂ (density: 2.32 g/cm³) and the film thickness is 50 nm, and the material for forming the impurity region 11A is indium oxide (density: 7.18 g/cm³) and the film thickness is 30 nm, the beam energy for the ion implantation process of boron ions is preferably about 20 keV.

When the SiO₂ film thickness of the second insulating layer is changed to 110 nm, 150 nm and 200 nm under the above conditions, suitable beam energy of the ion implantation process in each case is each of about 30 keV, about 40 keV and about 50 keV.

When the ion implantation process is performed, the substrate 12 of the stacked structure body to be subjected to the ion implantation process or the entire stacked structure body may be heated.

The temperature of the substrate 12 of the stacked structure body at the time of the indirect-implantation-type ion implantation process may be 15 to 450° C., it may be 20 to 450° C., it may be 50 to 450° C., it may be 100 to 400° C., it may be 150 to 400° C., and it may be 200 to 300° C.

By performing ion implantation of boron ions while heating the substrate 12 of the stacked structure body or the entire stacked structure body, the resistance value of the impurity region can be reduced to a value at which favorable semiconductor characteristics can be obtained with a smaller dose amount as compared with the case at room temperature.

After the indirect-implantation-type ion implantation process is performed, the stacked structure body may be subjected to a heat treatment.

The temperature of the heat treatment of the stacked structure body may be 100 to 400° C., it may be 200 to 350° C., and it may be 250 to 300° C.

The time for the heat treatment may be 0.1 to 5 hours, it may be 0.3 to 3 hours, and it may be 0.5 to 2 hours.

By performing the heat treatment at a temperature in the above range, a state where boron ions are uniformly diffused in the entire impurity region is easily obtained.

Boron ions in the impurity region 11A diffuse and enter the channel region 11B by the heat treatment (annealing) after the ion implantation process, so that the effective channel length L_{eff} is eroded and ΔL (a value of ½ of a difference between the gate width L and the effective channel length L_{eff}) may increase, but by setting the annealing condition to the above range, an increase in ΔL can be suppressed.

In the case of performing the heat treatment after the indirect-implantation-type ion implantation process is performed, it is preferable to perform the heat treatment in a state where a part of the second insulating layer 14 is patterned and a part of the impurity region 11A is exposed.

By performing the heat treatment in a state where a part of the impurity region 11A is exposed, excessive boron ions of the boron ions implanted into the impurity region 11A are released from the exposed region of the impurity region 11A to the outside, so that diffusion of boron ions from the impurity region 11A to the channel region 11B is suppressed. Therefore, the threshold voltage Vth in the thin film transistor is easily maintained around 0 V. After a contact hole is formed before the indirect-implantation-type ion implantation process is performed, the ion implantation process may be performed by irradiating a region other than the contact hole with ions, and then annealing may be performed.

The heat treatment after the ion implantation process may be performed in vacuum, in an inert gas (such as nitrogen and rare gas) atmosphere, or in a nitrogen atmosphere.

Preferably, the heat treatment is performed in an inert gas (such as nitrogen and rare gas) atmosphere showing an oxygen concentration of about 20%, and more preferably, the heat treatment is performed in an air atmosphere having a humidity of about 40%.

When the heat treatment is performed in an atmosphere appropriately containing oxygen or water, excessive boron ions among boron ions implanted into each layer of the stacked structure body react with oxygen or water entering from the outside of the stacked structure body, so that the boron ions are easily desorbed to the outside of the stacked structure body.

When a part of the impurity region 11A is exposed and subjected to the heat treatment, the reaction between boron ions and oxygen, water or the like tends to more easily proceed in the vicinity of the exposed region of the impurity region 11A.

### (Method for Producing Semiconductor Device of Second Embodiment: Direct Implantation)

The semiconductor device according to the second embodiment can be produced as follows, for example: an oxide thin film containing an oxide of In as a main component is formed on a lower layer or the like constituting the semiconductor device, such as a substrate, a buffer layer and an insulating layer, then the oxide thin film is patterned in a desired shape by using photolithography, and then annealing is performed as necessary to perform a crystallization treatment, thereby forming an oxide semiconductor layer in which the atomic percent of In is 70 atom % or more based on all metal elements (oxide semiconductor layer forming step); a second insulating layer covering the entire oxide semiconductor layer is formed on the surface of the oxide semiconductor layer (second insulating layer forming step); a metal layer is formed on a part of the second insulating layer of the oxide semiconductor layer (metal layer forming step); and then, boron ions are irradiated toward the oxide semiconductor layer and the metal layer (ion implantation processing step) in a state where the metal layer is patterned in a desired shape by using photolithography and the second insulating layer portion not overlapping the metal layer is removed to expose the surface of the oxide semiconductor layer at a portion not overlapping the metal layer (insulating layer removing step).

In the method for producing the semiconductor device according to the second embodiment, boron ions are directly irradiated to the surface of the oxide semiconductor layer portion exposed in the second insulating layer removing step. As a result, boron ions are directly implanted into the exposed oxide semiconductor layer portion, and an impurity region is formed in the oxide semiconductor layer. The portion of the oxide semiconductor layer overlapping the metal layer forms a channel region.

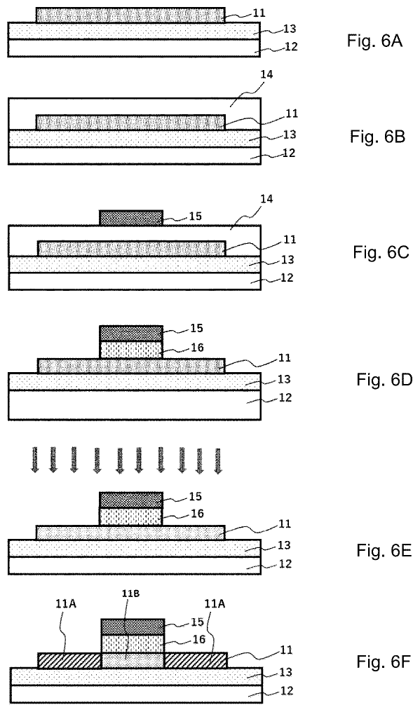

The first insulating layer forming step, the oxide semiconductor layer forming step (FIG. 6A), the second insulating layer forming step (FIG. 6B), and the metal layer forming step (FIG. 6C) in the method for producing the semiconductor device according to the second embodiment can be performed in the same manner as described in the method for producing the semiconductor device according to the first embodiment. Therefore, only steps different from the method for producing the semiconductor device according to the first embodiment will be described.

Hereinafter, each step of the method for producing the semiconductor device according to the second embodiment illustrated in FIG. 3 will be described with reference to FIGS. 6A-6F.

### Insulating Layer Removing Step

The step of removing a part of the second insulating layer (FIG. 6D) can be typically performed by patterning the metal layer formed on the surface of the second insulating layer 14 by photolithography and then patterning the second insulating layer 14 by photolithography using the same photoresist film in the metal layer forming step which is a previous step.

It is also possible to use a photoresist film different from that used for patterning the metal layer.

As a result, the surface of the oxide semiconductor layer in the region from which the second insulating layer has been removed is exposed.

### Ion Implantation Processing Step

By irradiating boron ions toward the oxide semiconductor layer 11 and the metal layer 15, boron ions are directly irradiated and implanted to the region of the oxide semiconductor layer 11 where the surface is exposed (FIG. 6E). On the other hand, in the region of the oxide semiconductor layer 11 covered with the metal layer 15, the metal layer 15 serves as a mask, and boron ions are not directly implanted.

As a result, the impurity region 11A having a predetermined average boron concentration is formed in a region of the oxide semiconductor layer 11 not covered with the metal layer 15, and the channel region 11B is formed in a region of the oxide semiconductor layer 11 covered with the metal layer 15 (FIG. 6F).

Some of the boron ions implanted into the oxide semiconductor layer 11 exposed at the time of the ion implantation process are diffused into the first insulating layer 13 at the time of the ion implantation process or at the time of the heat treatment described later.

The first impurity-added insulating film region 131 (see FIG. 3) is formed by the boron ions diffused in the first insulating layer 13 at the time of the ion implantation process or at the time of the heat treatment described later.

In the direct-implantation-type ion implantation process, the dose amount of boron ions may be 0.05×10¹⁵ ions/cm² or more, 0.1×10¹⁵ ions/cm² or more, 0.2×10¹⁵ ions/cm² or more, or 0.3×10¹⁵ ions/cm² or more, and it may be 6.0×10¹⁵ ions/cm² or less, 4.0×10¹⁵ ions/cm² or less, or 2.0×10¹⁵ ions/cm² or less.

By setting the dose amount of boron ions in the direct-implantation-type ion implantation process within the above range, an impurity region can be formed in the oxide semiconductor layer 11 in a state of having an appropriate resistance value.

The beam energy of the direct-implantation-type ion implantation process may be 0.1 keV to 1,000 keV, it may be 1 keV to 500 keV, and it may be 5 keV to 100 keV.

Suitable beam energy for the direct-implantation-type ion implantation process can be determined according to, for example, the material and film thickness for forming the impurity region 11A of the oxide semiconductor layer 11, and the relationship with the ion implantation species.

For example, it is possible to calculate suitable beam energy using TRIM which is software capable of simulating the ion implantation process by the Monte Carlo method.

Specifically, when the material for forming the impurity region 11A is indium oxide (density: 7.18 g/cm³) and the film thickness is 30 nm, the beam energy for the ion implantation process of boron ions is preferably about 5 keV.

Also in the case of the direct-implantation type, as in the case of the indirect-implantation type, when the ion implantation process is performed, the substrate 12 of the stacked structure body to be subjected to the ion implantation process or the entire stacked structure body may be heated.

The temperature of the substrate 12 of the stacked structure body at the time of the direct-implantation-type ion implantation process may be 15 to 450° C., it may be 20 to 450° C., it may be 50 to 450° C., it may be 100 to 400° C., it may be 150 to 400° C., and it may be 200 to 300° C.

Also in the case of the direct-implantation-type ion implantation process, as in the case of the indirect-implantation-type ion implantation process, the stacked structure body may be subjected to a heat treatment after the ion implantation process is performed.

The preferred temperature range, the range of the heat treatment time, and the heat treatment atmosphere in the case of performing the heat treatment of the stacked structure body after the ion implantation process can be the same as the preferred temperature range, the range of the heat treatment time, and the heat treatment atmosphere in the case of performing the heat treatment after the indirect-implantation-type ion implantation process.

The reason why these ranges and atmospheres are suitable is the same as those described in the heat treatment after the indirect-implantation-type ion implantation process.

In the method for producing the semiconductor device described with reference to FIGS. 5A-5E and 6A-6F, a case where the ion implantation process of irradiating ions toward the second insulating layer or the oxide semiconductor layer using the metal layer formed on the second insulating layer as a mask has been described as an example, but the method for producing the semiconductor device of the present aspect is not necessarily limited to such a method. For example, the ion implantation process may be performed using a resist of photolithography as a mask instead of the metal layer.

### 3. Thin Film Transistor (TFT)

The semiconductor device according to the present embodiment can be suitably used for a TFT.

In one embodiment, a TFT includes a buffer layer, a channel layer stacked on the buffer layer in contact with the buffer layer, a source electrode and a drain electrode each connected to the channel layer, and a gate electrode stacked on the channel layer via a gate insulating film, the channel layer is an oxide semiconductor layer included in the semiconductor device of the present invention, the gate insulating film is a gate insulating film region of the second insulating layer included in the semiconductor device of the present invention, the buffer layer is the first insulating layer included in the semiconductor device of the present invention, the source electrode and the drain electrode are a second metal layer and a third metal layer included in the semiconductor device of the present invention, and the gate electrode is a first metal layer included in the semiconductor device of the present invention.

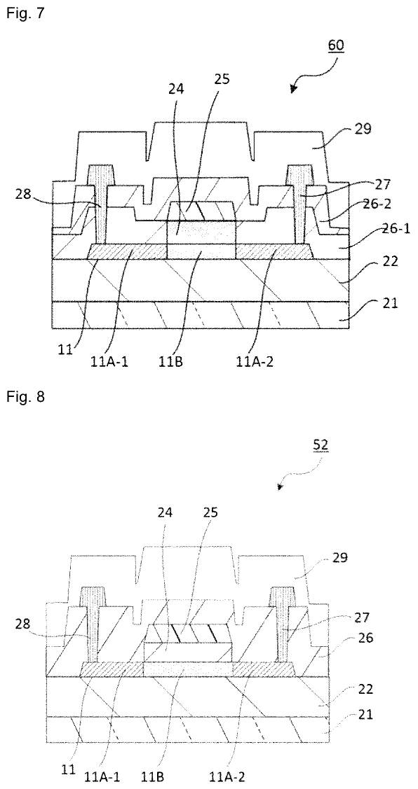

FIG. 7 described later illustrates a configuration in which a source electrode and a drain electrode are connected to impurity regions on both end sides of an oxide semiconductor layer, and a region in contact with a lower surface of a gate insulating film is a channel region. That is, a configuration is illustrated in which a region functioning as a gate insulating film is formed on the channel region, and a source electrode and a drain electrode are formed in the impurity region.

As the configuration of the TFT according to the present embodiment, for example, a known configuration can be adopted.

The TFT according to the present embodiment can be produced by adopting the above-described method for producing the semiconductor device. That is, there is provided a production method including: a forming step of an oxide semiconductor layer, the step including a step of forming an oxide thin film by sputtering using a sputtering target and using one or more gases selected from the group consisting of argon, nitrogen, hydrogen, water, and oxygen that are substantially free of impurity gases as sputtering gases (referred to as a film forming step of an oxide thin film in some cases) and a step of subjecting the oxide thin film to a heat treatment (referred to as a heat treatment step of the oxide thin film in some cases); a second insulating layer forming step of forming a second insulating layer in contact with the oxide semiconductor layer; a step of forming a metal layer on the oxide semiconductor layer (metal layer forming step); and a step of irradiating boron ions toward the oxide semiconductor layer and the metal layer to form an impurity region and a channel region (ion implantation processing step). The source electrode, the drain electrode, and the buffer layer can be formed by known materials and formation methods.

In the present specification, the mobility when Vd=0.1 V is applied is defined as linear mobility. Specifically, the mobility can be calculated by creating a transfer characteristic Id-Vg graph when Vd of Vd=0.1 V is applied, calculating the transconductance (Gm) of each Vg, and determining the mobility using a formula of a linear region.

In the following description, the current Id is a current between the source electrode and the drain electrode, the voltage Vd is a voltage (drain voltage) applied between the source electrode and the drain electrode, and the voltage Vg is a voltage (gate voltage) applied between the source electrode and the gate electrode.

The shape of the thin film transistor according to the present embodiment is not particularly limited, and a top-gate type transistor, a back channel etch type transistor, an etch stopper type transistor, or the like is preferable. These transistors may be self-aligned.

Hereinafter, embodiments will be described with reference to the drawings and the like. However, the embodiments can be implemented in many different modes, and those skilled in the art can easily understand that the forms and details can be variously changed without departing from the spirit and the scope thereof. Therefore, the present invention is not construed as being limited to the description of the following embodiments.

In the drawings, the size, layer thickness, region and the like may be exaggerated for clarity. Therefore, the present invention is not limited to the illustrated size, layer thickness, region and the like. The drawings schematically illustrate ideal examples, and the present invention is not limited to the shapes, values and the like illustrated in the drawings.

FIG. 7 is a schematic cross-sectional view of an example of a TFT having the configuration illustrated in FIG. 1 produced by adopting an indirect-implantation-type ion implantation process.

A TFT 60 is a top-gate type, and includes a substrate 21, a buffer layer (first insulating layer) 22, a channel layer (oxide semiconductor layer) 11, a second insulating layer 26-1 having a gate insulating film (gate insulating film region) 24, a gate electrode (first metal layer) 25, an interlayer insulating film 26-2, a source electrode 27, a drain electrode 28, and a protective film 29.

In the TFT illustrated in FIG. 7, a lower region of the gate electrode (first metal layer) 25 of the second insulating layer 26-1 corresponds to a gate insulating film.

The TFT 60 has a structure in which the substrate 21, the buffer layer 22 (first insulating layer), and the channel layer (oxide semiconductor layer) 11 are stacked in this order. The channel region 11B is provided at the center of the channel layer 11, and the gate insulating film (gate insulating film region) 24 and the gate electrode (first metal layer) 25 are stacked in this order on the channel region 11B. The gate insulating film (gate insulating film region) 24 is an insulating film that blocks conduction between the gate electrode (first metal layer) 25 and the channel layer (oxide semiconductor layer) 11.

Impurity regions 11A-1 and 11A-2 are provided on both sides of the channel region 11B in the oxide semiconductor layer 11. The impurity regions 11A-1 and 11A-2 are covered with the second insulating layer 26-1, and the gate electrode (first metal layer) 25 is covered with the interlayer insulating film 26-2.

Specifically, ions are implanted into the oxide semiconductor layer 11 via the second insulating layer 26-1 formed in the same step as the gate insulating film, thereby forming the impurity regions 11A-1 and 11A-2 in which the ion-implanted portions of the oxide semiconductor layer 11 have low resistance. In a region of the oxide semiconductor layer 11 overlapping the gate electrode (first metal layer) 25, ions are hardly implanted, and the channel region 11B in which the resistance is not reduced is formed.

The source electrode 27 is connected to the impurity region 11A-2, and the drain electrode 28 is connected to the impurity region 11A-1 via contact holes provided in the second insulating layer 26-1 and the interlayer insulating film 26-2. The source electrode 27 and the drain electrode 28 are conductive terminals for allowing a source current and a drain current to flow in the channel layer 11.

The protective film 29 is provided so as to cover the TFT constituent layers such as the interlayer insulating film 26-2, the source electrode 27 and the drain electrode 28.

FIG. 8 is a schematic cross-sectional view of an example of a TFT adopting the configuration illustrated in FIG. 3 produced by adopting a direct-implantation-type ion implantation process.

A TFT 52 has the same configuration as the TFT 60 illustrated in FIG. 7, except that the gate insulating film 24 is configured as an independent layer between the gate electrode (first metal layer) 25 and the channel layer (oxide semiconductor layer) 11.

In the TFT 52 produced by direct implantation of ions illustrated in FIG. 8, the impurity regions 11A-1 and 11A-2 are directly ion-implanted into the oxide semiconductor layer 11 without interposing the interlayer insulating film therebetween, thereby forming the impurity regions 11A-1 and 11A-2 with reduced resistance in the ion-implanted portions of the oxide semiconductor layer 11. In a region of the oxide semiconductor layer 11 overlapping the gate electrode (first metal layer) 25, ions are not implanted, and the channel region 11B in which the resistance is not reduced is formed.

The TFT of the present embodiment can be improved with a known configuration.

For example, although not illustrated, in the TFTs 60 and 52, a write shield layer may be formed between the substrate 21 and the buffer layer 22, or a write shield layer may be formed in an intermediate layer of the buffer layer 22 in which a plurality of layers are stacked.

In the TFTs 60 and 52, a second gate electrode (fourth metal layer) may be provided between the substrate 21 and the buffer layer 22, and the second gate electrode (fourth metal layer) may be provided in an intermediate layer of the buffer layer 22 in which a plurality of layers are stacked.

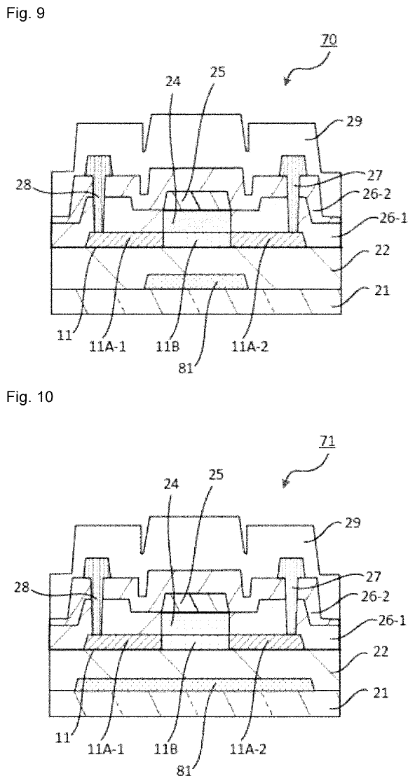

FIGS. 9 and 10 are schematic configuration diagrams of another example of the TFT of the present embodiment.

TFTs 70 and 71 have the same configuration as the TFT 60, except that a second gate electrode (fourth metal layer) 81 is provided between the substrate 21 and the oxide semiconductor layer 11.

The second gate electrode (fourth metal layer) 81 may be provided so as not to overlap the source electrode 27 and the drain electrode 28 as illustrated in FIG. 9, or may be provided so as to overlap the source electrode 27 and the drain electrode 28 and to overlap the entire region of the oxide semiconductor layer 11 in the source electrode 27-drain electrode 28 direction as illustrated in FIG. 10.

The second gate electrode (fourth metal layer) 81 may be electrically connected to the source electrode 27 or the gate electrode (first metal layer) 25 that is the first gate electrode.

The second gate electrode (fourth metal layer) 81 may be a floating electrode that is not electrically connected to other metal layers.

Electrical connection between the second gate electrode (fourth metal layer) 81 and another metal layer can have any configuration.

FIGS. 11A and 11B are schematic configuration diagrams of another example of the TFT of the present embodiment.

The basic configuration of a TFT 72 illustrated in FIGS. 11A and 11B is similar to that of the TFT 52 illustrated in FIG. 8, except that the gate electrode (first metal layer) 25 has a stacked structure including a first conductive layer 25-1 and a second conductive layer 25-2, and that a part of the end portion shape of the gate insulating film 24 and the protective film 26 has curvature.

The gate insulating film 24 and the gate electrode (first metal layer) 25 are stacked in this order on the channel region 11B at the center of the channel layer (oxide semiconductor layer) 11 of the TFT 72.

The source electrode 27 and the drain electrode 28 are directly connected to the impurity regions 11A-1 and 11A-2 provided on both sides of the channel region 11B in the oxide semiconductor layer 11, and the protective film 26 is provided so as to cover the source electrode 27, the drain electrode 28, the gate insulating film 24, and the gate electrode (first metal layer) 25.

The gate electrode (first metal layer) 25 has a structure in which a side end portion of the second conductive layer 25-2 protrudes outward from a side end portion of the first conductive layer 25-1.

As materials for forming the first conductive layer 25-1 and the second conductive layer 25-2, the material described as the material of the first metal layer can be used. The first conductive layer 25-1 and the second conductive layer 25-2 may be formed of different materials, or may be formed of the same material.

In one embodiment, a crystalline oxide semiconductor layer as a channel layer for the source electrode and the drain electrode has a channel length (a length in the source electrode 27-drain electrode 28 direction in the contact region between the oxide semiconductor layer 11 and the gate insulating film (gate insulating film region) 24 in FIGS. 7 and 8) of 1 μm or more and 50 μm or less, and a channel width (a length in the direction orthogonal to the source electrode 27-drain electrode 28 direction in the contact region between the oxide semiconductor layer 11 and the gate insulating film (gate insulating film region) 24 in FIGS. 7 and 8) of 1 μm or more and 80 μm or less.

The TFT of the present embodiment can be improved with a known configuration.

A material for forming the substrate is not particularly limited, and a generally used material can be arbitrarily selected. For example, a glass substrate, a ceramic substrate, a quartz substrate, or a sapphire substrate can be used. It is also possible to apply a single crystal semiconductor substrate such as silicon and silicon carbide, a polycrystalline semiconductor substrate, a compound semiconductor substrate such as silicon germanium, a silicon in insulator (SIO) substrate, or the like, and a substrate in which a semiconductor device is provided on these substrates may be used as the substrate.

A flexible substrate may be used as the substrate. As a method of providing a TFT on a flexible substrate, there is also a method for producing a TFT on an inflexible substrate, then peeling the TFT, and installing the TFT on a flexible substrate, in addition to a method for producing a TFT directly on a flexible substrate. In this case, a release layer may be provided between the inflexible substrate and the TFT.

As the substrate, various types of substrates can be used, and the substrate is not limited to a specific substrate. Examples of the substrate include a semiconductor substrate (for example, single crystal substrate or a silicon substrate), an SOI substrate, a glass substrate, a quartz substrate, a plastic substrate, a metal substrate, a stainless steel substrate, a substrate having a stainless steel foil, a tungsten substrate, a substrate having a tungsten foil, a flexible substrate, a laminated film, paper containing a fibrous material, base material film, or the like.

Examples of the glass substrate include barium borosilicate glass, aluminoborosilicate glass, soda lime glass, or the like.

Examples of the flexible substrate, the laminated film, the base material film, and the like include plastics typified by polyethylene terephthalate (PET), polyethylene naphthalate (PEN) and polyether sulfone (PES), and the like. Alternatively, examples of the material of the substrate include a synthetic resin such as acryl, and the like. Alternatively, examples of the material of the substrate include polypropylene, polyester, polyvinyl fluoride, polyvinyl chloride, and the like.

Alternatively, examples of the material of the substrate include polyamide, polyimide, aramid, epoxy, an inorganic vapor-deposited film, paper, and the like. In particular, by producing a transistor using a semiconductor substrate, a single crystal substrate, an SOI substrate, or the like, it is possible to produce a transistor having small variations in characteristics, size, shape, or the like, high current capability, and small size. When a circuit is constituted by such a transistor, it is possible to achieve low power consumption of the circuit or high integration of the circuit.

A flexible substrate may be used as a substrate, and a transistor may be formed directly on the flexible substrate.

Alternatively, a release layer may be provided between the substrate and the transistor.

The release layer can be used to partially or entirely complete a semiconductor device thereon, separate the semiconductor device from a substrate, and transfer the semiconductor device on another substrate. At that time, the transistor can also be transferred on a substrate having poor heat resistance or a flexible substrate. For the above-described release layer, for example, a configuration of a stacked structure of an inorganic film of a tungsten film and a silicon oxide film, a configuration in which an organic resin film of polyimide or the like is formed on a substrate, or the like can be used.

Examples of the substrate on which the transistor is transferred include a paper substrate, a cellophane substrate, an aramid film substrate, a polyimide film substrate, a stone substrate, a wood substrate, a cloth substrate (including natural fibers (silk, cotton, hemp), synthetic fibers (nylon, polyurethane, polyester), regenerated fibers (including acetate, cupra, rayon, recycled polyester) or the like), a leather substrate, a rubber substrate, or the like, in addition to the substrate on which the transistor can be formed. By using these substrates, it is possible to achieve formation of a transistor having favorable characteristics, formation of a transistor having low power consumption, production of an apparatus that is difficult to break, imparting heat resistance, weight reduction, or thickness reduction.

The buffer layer 22 may be composed of a single layer, or it may be composed of two or more layers. A metal layer may be provided between the buffer layer 22 and the substrate 21.

However, the channel layer 11 and the buffer layer 22 are preferably in direct contact with each other as illustrated in FIGS. 7 and 8, and the buffer layer 22 in direct contact with the channel layer 11 corresponds to the first insulating layer.

When the buffer layer 22 is composed of two or more layers, a layer in direct contact with the channel layer (oxide semiconductor layer) 11 in the buffer layer 22 is the first insulating layer.

As a material for forming the buffer layer in direct contact with the channel layer (oxide semiconductor layer) 11, the material described as the material of the first insulating layer can be used.

A material for forming the buffer layer not in direct contact with the channel layer (oxide semiconductor layer) 11 is not particularly limited, and a generally used material can be arbitrarily selected, and a stacked film can also be used as the buffer layer. For example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN can be used. The oxidation number of each material may vary. A flexible organic resin, polyimide, or the like can also be used.

The write shield layer may be connected to the source electrode 27 or may be connected to the gate electrode 25.

A material for forming the write shield layer is not particularly limited, and a generally used material can be arbitrarily selected. Specific examples thereof include metal electrodes such as Al, Ag, Cu, Cr, Ni, Co, Mo, Au, Ti, Zr, Ru, Y, Nb, Ta and W, metal electrodes made of an alloy containing two or more of these metals, and the like. A stacked electrode of two or more layers can also be used.

A second buffer layer may be provided between the write shield layer and the substrate 21. A material for forming the second buffer layer is also not particularly limited, and a generally used material can be arbitrarily selected, and a stacked film can be used as the second buffer layer. As the material of the second buffer layer, for example, SiO₂, SiNx, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN can be used. The oxidation number of each material may vary.

As a material for forming the gate insulating film, the material described as the material of the second insulating layer can be used.

A material for forming the drain electrode, the source electrode, and the gate electrode is not particularly limited, and a generally used material can be arbitrarily selected. Specific examples thereof include transparent electrodes such as ITO, IZO, ZnO and SnO₂, metal electrodes such as Al, Ag, Cu, Cr, Ni, Co, Mo, Au, Ti, Zr, Ru, Y, Nb, Ta and W, metal electrodes made of an alloy containing two or more of these metals, or the like. A stacked electrode of two or more layers can also be used.

A material for forming each interlayer insulating film is also not particularly limited, and a generally used material can be arbitrarily selected, and a stacked film can be used as the interlayer insulating film. For example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN can be used. The oxidation number of each material may vary.

Regardless of the structure of the TFT, it is preferable to provide a protective film on the drain electrode, the source electrode, and the conductive region. In the case of a bottom gate type, it is preferable to provide a protective film on the channel layer. By providing the protective film, durability is easily improved even when the TFT is driven for a long time.

The method for forming the buffer layer, the gate insulating film, the interlayer insulating film, and the insulating film of the protective film is not particularly limited. Examples of the formation method include PE-CVD, ALD, PLD, MO-CVD, RF sputtering, ICP sputtering, reactive sputtering, ICP-CVD, ion plating, a sol-gel method, a coating method, mist CVD, and the like. Tetraethoxysilane (TEOS) can also be used as gas species of PE-CVD in addition to silane (SiH₄).

For example, in the case of forming by PE-CVD, the process may be performed at a high temperature. The protective film or the insulating film often contains an impurity gas immediately after film formation, and it is preferable to perform a heat treatment (annealing treatment). By removing the impurity gas by the heat treatment, a stable protective film or insulating film is obtained, and a TFT having high durability is easily formed.

An S value (Swing Factor) is a value indicating steepness of the drain current rising steeply from the OFF state to the ON state when the gate voltage is increased from the OFF state.

The smaller the S value, the steeper the rise. When the S value is large, it is necessary to apply a high gate voltage at the time of switching from on to off, and power consumption may increase.

The S value of the TFT is preferably 0.8 V/dec or less, more preferably 0.6 V/dec or less, more preferably 0.5 V/dec or less, and still more preferably 0.3 V/dec or less. When the S value is 0.8 V/dec or less, there is a possibility that the driving voltage decreases and the power consumption can be reduced. In particular, in the case of use in an organic EL display, setting the S value to 0.3 V/dec or less for direct current drive is preferable because the power consumption can be greatly reduced.

A method for measuring the S value will be described in detail in Examples.

The on-off ratio is preferably 10⁶ or more, more preferably 10⁷ or more, and still more preferably 10⁸ or more. When the on-off ratio is 10⁶ or more, the liquid crystal display can be driven. When the on-off ratio is 10⁸ or more, an organic EL device with high contrast can be driven. When the on-off ratio can be set to 10¹⁰ or more and the off-current can be set to 10⁻¹² A or less, it is possible to provide a display device that can be driven at a low frequency of about 1 Hz and is excellent in low consumption.

The on-off ratio is obtained by determining the ratio [On current value/Off current value] with the value of Id of Vd=10 V and Vg=−10 V as the Off current value and the value of Id of Vd=10 V and Vg=20 V as the On current value.

The Off current value is preferably 10⁻¹⁰ A or less, more preferably 10⁻¹¹ A or less, and still more preferably 10⁻¹² A or less. When the Off current value is 10⁻¹⁰ A or less, an organic EL with high contrast can be driven. In the case of use in a transfer transistor or a reset transistor of a CMOS image sensor, it is possible to lengthen the image retention time or improve the sensitivity.

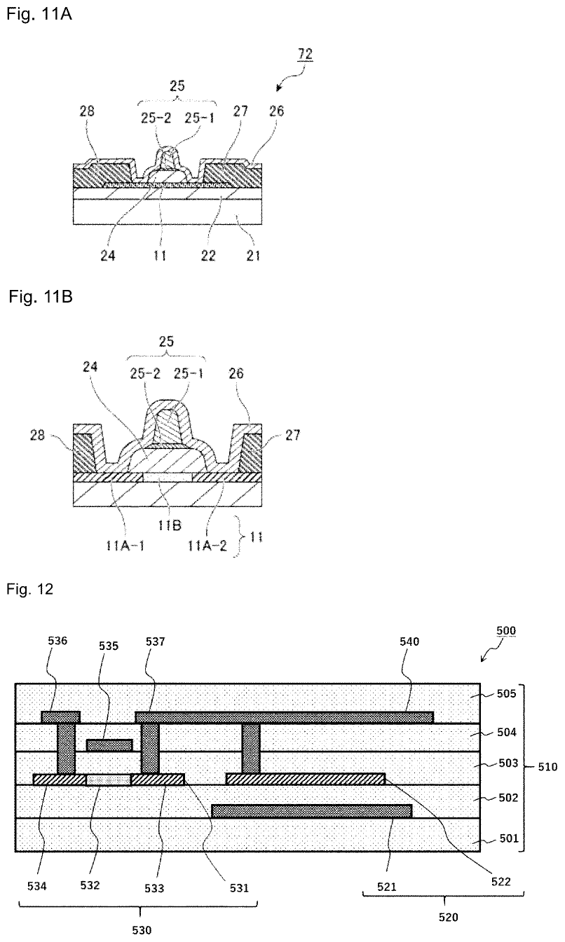

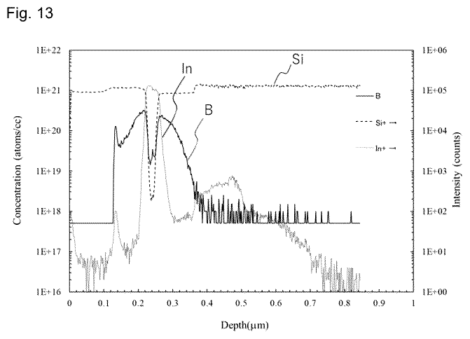

FIG. 12 is a cross-sectional view schematically illustrating a configuration of an apparatus having a semiconductor device according to an embodiment of the present invention.

In FIG. 12, an apparatus 500 has a structure in which a holding capacitor 520 and an oxide semiconductor TFT 530 are formed in a stacked structure body 510 in which insulating films 501 and 502 corresponding to a first insulating layer, an insulating film 503 corresponding to a second insulating layer, an interlayer insulating film 504, and a planarizing film 505 are stacked in this order on a substrate (not illustrated).

The oxide semiconductor TFT 530 corresponds to the semiconductor device of the present aspect.

The holding capacitor 520 includes a lower electrode 521 provided on the insulating film 501, an upper electrode 522 provided on the insulating film 502 so as to face the lower electrode 521, and an insulating region formed by a portion of the insulating film 502 between the upper electrode 522 and the lower electrode 521.

The oxide semiconductor TFT 530 includes an oxide semiconductor layer 531 provided on the insulating film 502, a gate electrode 535 provided on the insulating film 503, source electrode/drain electrode 536 and 537 provided penetrating the interlayer insulating film 504 and the insulating film 503, and a gate insulating region that interrupts conduction between the oxide semiconductor layer 531 and the gate electrode 535.

Each of the source electrode/drain electrode 536 and 537 is connected to each of impurity regions 533 and 534 provided on both sides of the channel region 532 of the oxide semiconductor layer 531 via contact holes provided in the third insulating film 503 and the fourth insulating film 504.

The gate insulating region is formed by a portion in the third insulating film 503 between the gate electrode 535 and the channel region 532.

The source electrode/drain electrode 536 and 537 of the oxide semiconductor layer 531 are provided on one end side of a series of conductor layers provided on the fourth insulating film 504, and the remaining portion of the conductor layer constitutes a connection portion 540.

The connection portion 540 is connected to the upper electrode 522 of the holding capacitor 520 via contact holes formed in the third insulating film 503 and the fourth insulating film 504.

In other words, the source electrode/drain electrode 537 of the oxide semiconductor TFT 530 and the upper electrode 522 of the holding capacitor 520 are connected to each other by the connection portion 540.

As a material for forming the substrate (not illustrated), the material described as the material of the substrate can be used.

As materials for forming the first insulating film 501, the second insulating film 502, the third insulating film 503, the fourth insulating film 504, and the planarizing film 505, the material described as the material of each interlayer insulating film can be used.

The conductor layers constituting the gate electrode 535 and the lower electrode 521, and the conductor layers constituting the source electrode/drain electrode 536 and 537 and the connection portion 540 can be configured using the materials described as the materials of the drain electrode, the source electrode, and the gate electrode.

The upper electrode 522 is usually configured using the materials described as the materials of the drain electrode, the source electrode, and the gate electrode, but may be configured using the same material as the oxide semiconductor layer 531, and boron may be ion-implanted to operate as an electrode.

The TFT according to the present embodiment can be suitably used for solar cells, display devices such as liquid crystal devices, organic electroluminescence devices and inorganic electroluminescence devices, and electronic apparatuses such as power semiconductor devices and touch panels.

The thin film transistor according to the present embodiment can also be applied to various integrated circuits such as a field effect transistor (MOSFET or MESFET), a logic circuit, a memory circuit, and a differential amplification circuit, and these can be applied to an electronic apparatus, an electric apparatus, a vehicle, a power engine, or the like. The thin film transistor according to the present embodiment can be applied not only to a field effect transistor but also to an electrostatic induction transistor and a Schottky barrier transistor.

The thin film transistor according to the present embodiment can be suitably used for a display device such as a portable and in-vehicle display device, a solid-state imaging device, and the like. The thin film transistor according to the present embodiment can also be suitably used as a transistor for a flat panel detector for an X-ray image sensor for medical use.

The oxide semiconductor layer according to the present embodiment can also be applied to a Schottky diode, a resistance change type memory, and a resistor.

### EXAMPLES

Hereinafter, the present invention will be specifically described based on specific examples of semiconductor devices. The present invention is not limited to these examples.

### Production of Self-Aligned Top-Gate Structure Small TFT

### Production Example of TFT Device by Indirect Ion Implantation

### Examples 1 to 8 and Comparative Examples 1 to 7

A thin film transistor (TFT) was produced by the following steps.

A thin film transistor (TFT) produced by the following steps has the same configuration as the thin film transistor (TFT) 60 illustrated in FIG. 7, except that the thin film transistor does not have the protective film 29, and thus the following description will be given using reference numerals illustrated in FIG. 7.

### (1) Formation of Buffer Layer (First Insulating Layer) 22

A SiOₓ layer (buffer layer 22) having a thickness of 300 nm was formed on an alkali-free glass substrate 21 having a diameter of 4 inches by sputtering using a SiO₂ sputtering target.

### (2) Formation of Oxide Thin Film

Next, sputtering was performed using an oxide sputtering target to form an oxide thin film having a film thickness shown in Tables 1 to 3.

As the oxide sputtering target, a material A and a material B described in the column of “Material of oxide semiconductor layer” described in Tables 1 to 3 described later were used.

The material A and the material B are oxide sputtering targets made of an oxide containing at least In and Ga.

### (3) Formation of Oxide Semiconductor Layer 11

Next, the oxide thin film was patterned in an island shape by photolithography to form the oxide semiconductor layer 11. First, a photoresist film was formed on the oxide thin film. AZ1500 (manufactured by AZ Electronic Materials) was used as a photoresist. Exposure was performed through a photomask having a pattern formed in a width of 50 μm×a length of 20 μm. After the exposure, the film was developed with tetramethylammonium hydroxide (TMAH). After the development, the oxide thin film was etched with oxalic acid (ITO-06N manufactured by KANTO CHEMICAL CO., INC.). After the etching, the photoresist was removed to obtain the substrate 21 with a patterned oxide thin film (oxide semiconductor layer 11).

### (4) Annealing

Next, the substrate 21 on which the oxide semiconductor layer 11 was formed was placed in a furnace, heated to 350° C. at a temperature increase rate of 10° C./min in the air, and then held for an hour. The inside of the furnace was held at 350° C. for an hour and then allowed to cool naturally, and the substrate 21 was taken out of the furnace after the internal temperature of the furnace returned to room temperature.

### (5) Film Formation of Second Insulating Layer (Layer Including Gate Insulating Film) 26-1

Next, sputtering was performed using a SiO₂ sputtering target to form a SiOₓ layer (second insulating layer 26-1) having a thickness of 100 nm.

### (6) Annealing of Second Insulating Layer 26-1

Next, the substrate 21 on which the second insulating layer 26-1 was formed was placed in a furnace, heated to 400° C. at a temperature increase rate of 10° C./min in the air, and then held for an hour. The inside of the furnace was held at 400° C. for an hour and then allowed to cool naturally. After the temperature in the furnace returned to room temperature, the substrate 21 was removed from the furnace.

### (7) Formation of Gate Electrode 25

Next, a Mo film having a thickness of 150 nm was formed by sputtering using a Mo sputtering target.

### (8) Patterning of Gate Electrode 25

Next, the Mo film was patterned in an island shape by photolithography. First, a photoresist film was formed on the channel layer. AZ1500 (manufactured by AZ Electronic Materials) was used as a photoresist. Exposure was performed through a photomask having a pattern formed in a size of a width of 10 μm×a length of 28 μm. After the exposure, the film was developed with tetramethylammonium hydroxide (TMAH). After the development, the Mo film was etched with PAN (mixed acid of phosphoric acid, nitric acid, and acetic acid) to form the gate electrode 25.

### (9) Ion Implantation Process

Boron ions were implanted into the oxide semiconductor layer 11.

The ion implantation was performed by placing the substrate formed up to the gate electrode 25 on a sample stage of an ion implantation apparatus and irradiating boron ions mass-separated from the BF₃ gas as a gas source toward the second insulating layer 26-1 and the gate electrode 25 by the ion implantation apparatus.

Each of the beam energy and the temperature of the sample stage (temperature of the substrate) during the ion implantation process is shown in the columns “Beam energy” and “Substrate temperature during ion implantation” in Tables 1 to 3, and the dose amount of boron ions by ion implantation is shown in the column of “Dose amount” in Tables 1 to 3.

Next, the substrate after the ion implantation process was placed in a furnace and annealed at 300° C. for an hour in the air.

### (10) Formation of Interlayer Insulating Film 26-2

Next, sputtering was performed using a SiO₂ sputtering target to form a SiOₓ layer (interlayer insulating film 26-2) having a thickness of 150 nm.

### (11) Formation of Contact Holes of Second Insulating Layer 26-1 and Interlayer Insulating Film 26-2

The substrate on which the second insulating layer 26-1 and the interlayer insulating film 26-2 were formed was exposed to light through a photomask using a photoresist AZ1500 (manufactured by AZ Electronic Materials), and then developed with tetramethylammonium hydroxide (TMAH). After the development, contact holes were formed in the second insulating layer 26-1 and the interlayer insulating film 26-2 by buffered hydrofluoric acid (BHF).

### (12) Formation of Source Electrode 27 and Drain Electrode 28

Next, a Mo layer having a thickness of 150 nm was formed and patterned by sputtering.

### (13) Final Annealing

Finally, annealing was performed at 200° C. for an hour in a N₂ atmosphere to obtain a self-aligned top-gate structure small TFT device 1.

Tables 1 to 3 summarize the TFT production conditions.

### Comparative Example 8

The process “(9) Ion implantation process” was performed in the same manner as in Examples 1 to 8 and Comparative Examples 1 to 7 (Production Example of TFT device by indirect ion implantation), except that the ions to be irradiated toward the second insulating layer 26-1 and the gate electrode 25 were changed from boron ions to argon ions by the ion implantation apparatus in “(9) Ion implantation process”.

Except for the above, a TFT device was produced in the same manner as described in Examples 1 to 8 and Comparative Examples 1 to 7 (Production Example of TFT device by indirect ion implantation).

### Production Example of TFT Device by Direct Ion Implantation

### Examples 9 to 11 and Comparative Examples 9 to 13

A thin film transistor (TFT) was produced by the following steps.

A thin film transistor (TFT) produced by the following steps has the same configuration as the thin film transistor (TFT) 52 illustrated in FIG. 8, except that the thin film transistor does not have the protective film 29.

In “(8) Patterning of gate electrode 25”, after the Mo film was etched to form the gate electrode 25, the second insulating layer 26-1 was etched with buffered hydrofluoric acid (BHF) before peeling off the photoresist, and the second insulating layer 26-1 was patterned. As a result, the surface of the region of the oxide semiconductor layer 11 not overlapping the gate electrode 25 was exposed, and the gate insulating film 24 composed of the rest of the second insulating layer 26-1 after patterning was formed between the gate electrode 25 and the oxide semiconductor layer 11. Except for the above, the process “(8) Patterning of gate electrode 25” was performed in the same manner as in Examples 1 to 8 and Comparative Examples 1 to 8 (Production Example of TFT device by indirect ion implantation).

Subsequently, in “(9) Ion implantation process”, boron ions mass-separated from the BF₃ gas as a gas source were irradiated with an ion implantation apparatus toward the oxide semiconductor layer 11 and the gate electrode 25 whose surfaces were partially exposed, thereby implanting boron ions into the oxide semiconductor layer 11.

The process “(9) Ion implantation process” was performed in the same manner as in Examples 1 to 8 and Comparative Examples 1 to 7 (Production Example of TFT device by indirect ion implantation), except that each of the beam energy and the temperature of the sample stage (temperature of the substrate) during the ion implantation process was changed as shown in the columns of “Beam energy” and “Substrate temperature during ion implantation” in Table 3, and the dose amount of boron ions by the ion implantation was changed as shown in the column of “Dose amount” in the table.

Except for the above, a TFT device was produced in the same manner as described in Examples 1 to 8 and Comparative Examples 1 to 7 (Production Example of TFT device by indirect implantation).

### Comparative Example 14

The process “(9) Ion implantation process” was performed in the same manner as in Examples 9 to 11 and Comparative Examples 9 to 13 (Production Example of TFT device by direct ion implantation), except that the ions to be irradiated toward the oxide semiconductor layer 11 and the gate electrode 25 whose surfaces were partially exposed were changed from boron ions to argon ions by the ion implantation apparatus in “(9) Ion implantation process”.

Except for the above, a TFT device was produced in the same manner as described in Examples 9 to 11 and Comparative Examples 9 to 13 (Production Example of TFT device by direct ion implantation).

### Characteristic Evaluation

The TFTs obtained in Examples and Comparative Examples were evaluated as follows. The results are shown in Tables 1 to 3. In the Tables, “E+XX” means “×10^{XX}”.

### (A) Evaluation on Oxide Semiconductor Layer of TFT

(a) Crystallinity (Polycrystalline/Amorphous) of Oxide Semiconductor Layer after TFT Production

For the crystalline state of the cross section of the oxide semiconductor layer in the TFT, the oxide semiconductor layer was pretreated using a focused ion beam (FIB), and the crystalline state was evaluated by observing the cross section of the oxide semiconductor layer with a transmission electron microscope (TEM).

Specifically, first, an ion beam was applied in a direction perpendicular to the surface of the oxide semiconductor layer using a FIB (“FB2100 type” manufactured by Hitachi High-Technologies Corporation) apparatus, and a test piece of 16 μm×4 μm was sampled. Thereafter, for the sampled test piece, a total of two samples were extracted, one for each of a region of 3 μm from an end of a region where impurity regions of the source electrode or the drain electrode and the oxide semiconductor layer overlap in the channel length direction (horizontal direction in the drawing) toward a region which does not overlap, and a region of 3 μm from an end of a region where the channel regions of the gate electrode and the oxide semiconductor layer overlap toward the overlapping region. Ar ion milling was performed on the two extracted samples in a channel width direction (depth direction in the drawing) perpendicular to the channel length direction and the film thickness direction until the thickness of the thin piece reached about 100 nm, and the thickness of the two extracted samples was reduced. When crystal grains could not be confirmed due to ion sputtering damage during FIB processing, etching was repeatedly performed with Ar ion milling (“Model691” manufactured by Gatan) at an ion gun voltage of 4 keV until crystal grains could be confirmed.

As a cross-sectional TEM image, an image at an observation magnification of 100,000 times (area of about 4 μm square) was observed using a transmission electron microscope (“JEM-2800 type” manufactured by JEOL Ltd.) at an acceleration voltage of 200 kV.

For the determination method of the crystalline state, the crystalline state was determined by observing an electron beam diffraction pattern of a sample obtained by observing a cross-sectional TEM image.

Specifically, using an electron microscope (“JEM-2800 type” manufactured by JEOL Ltd.), the oxide thin film area observed in the cross-sectional TEM image was irradiated with an electron beam at an irradiation area of about 100 nmφ and an acceleration voltage of 200 kV by a selected area aperture, and the diffraction pattern was measured with the camera length set to 2 m.

An oxide thin film from which a clear diffraction spot was not obtained in arbitrary three fields of view extracted so that observation points did not overlap in the channel length direction in the cross-sectional TEM image sample was determined as “amorphous”. On the other hand, the oxide thin film in which diffraction points having symmetry were observed from the diffraction pattern was determined as “crystalline”. A case where the oxide semiconductor layer present in parallel with the substrate surface had a grain boundary perpendicular to the substrate surface was determined as “polycrystalline”.

As a result of the above measurement, it was confirmed that the oxide semiconductor layers of the TFTs obtained in Examples 1 to 11 and Comparative Examples 1 to 14 were polycrystalline.

### (b) Identification of Crystal Structure by Electron Beam Diffraction

Whether or not the crystal structure of the oxide semiconductor layer in the TFT was a bixbyite structure was evaluated by observing the electron beam diffraction pattern of the sample obtained by observing the cross-sectional TEM image.

Specifically, using an electron microscope (“JEM-2800 type” manufactured by JEOL Ltd.), the oxide thin film area observed in the cross-sectional TEM image was irradiated with an electron beam at an irradiation area of about 100 nmφ and an acceleration voltage of 200 kV by a selected area aperture, and the diffraction pattern was measured with the camera length set to 2 m.

In order to identify the crystal structure, simulation of the electron diffraction pattern of the bixbyite structure of In₂O₃ performed using electron diffraction simulation software ReciPro (free software ver 4.641 (2019/03/04)). In the simulation, 14388 of ICSD (Inorganic Crystal Structure Database: Japan Association for International Chemical Information) was used as crystal structure data of a bixbyite structure, a space group: Ia-3, a lattice constant: a=10.17700 Å, an atomic coordinate In site (0.250, 0.250, 0.250), In site (0.466, 0.000, 0.250), and O site (0.391, 0.156, 0.380) were used.

With a camera length of 2 m, simulation was performed using 11 types of reciprocal lattice vectors (1 0 0), (1 1 1), (1 1 0), (2 1 1), (3 1 1), (2 2 1), (3 3 1), (2 1 0), (3 1 0), (3 2 1), and (2 3 0) as incident electron beam directions.

The electron beam diffraction pattern of the oxide thin film was compared with the result of the diffraction spot for the obtained simulation pattern, and when the result coincided with any of 11 kinds of simulation patterns, it was determined that the oxide thin film contained crystal grains having a bixbyite structure.

As a result of the above measurement, it was confirmed that crystal grains having a bixbyite structure were contained in the oxide thin films of the TFTs obtained in Examples 1 to 11 and Comparative Examples 1 to 14.

### (c) Average in Concentration (In-Containing Amount) in Oxide Semiconductor Layer

The In concentration in the oxide semiconductor layer (average concentration of In (indium) with respect to all detectable metal atoms contained in the oxide semiconductor layer) of each of the TFTs obtained in Examples and Comparative Examples was measured by transmission electron microscopy-energy dispersive X-ray spectroscopy (TEM-EDX).

The average In concentration in the oxide semiconductor layer was measured by TEM-EDX as follows.

First, the TFT obtained in each of Examples and Comparative Examples was subjected to focused ion beam (FIB) processing at an acceleration voltage of 20 to 30 kV by a composite beam machining observation apparatus (“JIB-4700F” manufactured by JEOL Ltd.), and then a thin film sample for cross-sectional TEM observation was picked up by a microsampling method at an acceleration voltage of 40 kV by a focused ion beam machining observation apparatus (FIB) (“FB-2100” manufactured by Hitachi High-Tech Co., Ltd.).

A thin film sample for cross-sectional TEM observation by TEM-EDX was prepared as a thin film including the entire region in the thickness direction of the oxide semiconductor layer (the stacking direction of the TFT), and was prepared so as to have the same sample film thickness (film thickness: 60 to 80 nm) in all Examples and Comparative Examples.

Next, the thin film sample for cross-sectional TEM observation was subjected to cross-sectional TEM observation, and EDX line analysis was performed in the film thickness direction from the first insulating layer 13 side to the second insulating layer 14 side for the field of view at the central portion of the channel region in the field of view including the oxide semiconductor layer.

The EDX analysis was performed by an energy dispersive X-ray analyzer (“JED-2300T” manufactured by JEOL Ltd.) under the following conditions.
Acceleration voltage: 200 kV
Measurement mode: STEM mode
Spot diameter: 0.16 nm
Measurement interval: 1 nm

The EDX analysis was performed by selecting, as elements to be detected (detectable elements), all metal elements that are constituent elements of the oxide semiconductor layer, the second insulating layer and the first insulating layer, and that can be detected by the device in addition to In, and performing line analysis in the film thickness direction of the oxide semiconductor layer.

The EDX spectral intensity obtained by the EDX line analysis was automatically calculated using an initial setting value by exclusive software of an energy dispersive X-ray analyzer (“JED-2300T” manufactured by JEOL Ltd.) to calculate an average In concentration.

The average In concentration was calculated by arithmetically averaging each In concentration in a region in the film thickness direction in which In was a main component, which was calculated based on the In amount acquired at each measurement point in the EDX line analysis described above.

### (d) Resistance Value of Impurity Region

The resistance value of the impurity region 11A of the oxide semiconductor layer 11 of the TFT obtained in each of Examples and Comparative Examples was measured as follows.

First, a set of probes of a resistance measuring instrument was inserted into impurity regions of the TFT devices obtained in Examples and Comparative Examples, and a resistance value R was measured.

When the probe cannot be inserted into the sample and when there is a semiconductor device in which three or more types of TFTs having a channel width fixed to one value and channel lengths different from each other are to be measured, a value of R₀ calculated by transmission line method (TLM) analysis described in item (e) described later may be regarded as the resistance value R.

Based on the obtained resistance measured value R, the sheet resistance and the specific resistance were calculated based on the formulas (2) and (3) calculated from the following relational formula (1).

$$ρ = R \times L / W \times d \qquad ( 1 )$$

$$Rsh = R \times L / W \qquad ( 2 )$$

$$ρ = Rsh \times d \qquad ( 3 )$$

In the above formulas (1) to (3), p is a specific resistance, Rsh is a sheet resistance, d is a film thickness of the oxide semiconductor layer, R is a resistance measured value measured by a resistance measuring instrument, a channel length L is a length in a source/drain direction of the oxide semiconductor layer, and a channel width W is a width (width with respect to the length L) of the oxide semiconductor layer. When the region formed by L and W is not rectangular, the specific resistance is calculated by applying a method capable of excluding the shape factor, such as Van der Pauw method.

### (e) ΔL (Value of ½ of Difference Between Gate Width L and Effective Channel Length L_{eff})

The TFT devices obtained in Examples and Comparative Examples were subjected to transmission line method (TLM) analysis to calculate ΔL in the oxide semiconductor layer. Tables 1 to 3 show the values of ΔL.

The TLM analysis is a method for calculating an effective channel length (L_{eff}) and an estimated value of an external resistance by acquiring characteristic information on a resistance value (R) and a gate width (L) of a TFT device (thin film transistor) for each of a plurality of gate voltages (Vg) for each TFT and obtaining intersection coordinates of graphs obtained based on the following Relational formulas (A) and (B) when three or more kinds of TFTs having three or more gate widths L with the same gate length W are present on a semiconductor device.

A relational formula between a series resistance (R_{T}) between the source electrode and the drain electrode and the gate width (L) is given by the following formulas (A) and (B).

$${R}_{T} = {V}_{DS} / {I}_{D} = 2 {R}_{0} + {r}_{c h} \cdot {L}_{eff} \qquad ( A )$$

$${L}_{eff} = L - 2 Δ L \qquad ( B )$$

In the above formulas (A) and (B), R_{T} is a total resistance, R₀ is an external resistance, L_{eff} is an effective channel length, L is a gate width, and ΔL is a value of ½ of the difference between the gate width L and the effective channel length L_{eff}. r_{ch} is obtained by dividing the channel resistance by the unit length, and depends on the gate voltage (V_{g}).

In the formulas (A) and (B), VDs is a source-drain voltage, and Ip is a drain current.

The “gate width L” in the formulas (A) and (B) is indicated as the gate width L1 in FIGS. 1 and 3, and the “effective channel length L_{eff}” is indicated as L2 in FIGS. 1 and 3.

“ΔL” in the formulas (A) and (B) corresponds to an average value of ΔL₁ and ΔL₂ in FIGS. 1 and 3. Examples 1 to 11 and Comparative Examples 1 to 14 are TFTs having a structure in which ΔL₁ and ΔL₂ in FIGS. 1 and 3 are the same. When the above-described TLM analysis is performed, 2ΔL, which is a value obtained by subtracting the effective channel length L_{eff} from the gate width L described in the formula (B), is determined. Here, since L−L_{eff} also represents ΔL₁+ΔL₂, when ΔL1=ΔL₂, ΔL coincides with ΔL₁.

As described above, the information on the resistance value (R; R_{T}) and the gate width (L) characteristic of the TFT device (thin film transistor) acquired for each of the plurality of gate voltages (V_{g}) was plotted as (x, y)=(gate width L, total resistance R_{T} of the TFT device) to obtain a x value of the intersection coordinates of a plurality of graphs, and the fact that x value coincides with 2ΔL was used to calculate ΔL. A y value of the intersection coordinates corresponds to the external resistance (2R₀).

The TLM method, which is a method of calculating ΔL described above, can be applied only to a case where three or more types of TFTs having three or more gate widths L with the same gate length W are present on the semiconductor device and the graph can be created.

Therefore, when the graph cannot be created (for example, when reverse engineering is performed), ΔL (ΔL₁ and/or ΔL₂) may be measured by, for example, a method using a scanning spread resistance microscope (SSRM) or a scanning capacitance microscopy (SCM). Although the ΔL value determined by the TLM method and the ΔL value measured by a method using SSRM, SCM or the like substantially coincide with each other, the value can be corrected to the value of the TLM standard by preparing and correcting a standard sample.

### (B) Average Boron Concentration of Oxide Semiconductor Layer (Impurity Region/Channel Region), First Impurity-Added Insulating Film Region, Second Impurity-Added Insulating Film Region and Gate Insulating Film Region

Each layer of the TFT devices obtained in Examples and Comparative Examples was etched without pretreatment, SIMS depth direction analysis by time-of-flight secondary ion mass spectrometry (ToF-SIMS) was performed using a time-of-flight secondary ion mass spectrometer (“TOF-SIMS5” manufactured by ION-TOF Corporation), elements existing in the depth direction were analyzed by detecting the intensity of secondary ions, and the boron concentration in the impurity region and the channel region of the oxide semiconductor layer, the first impurity-added insulating film region of the first insulating layer, the second impurity-added insulating film region, and the gate insulating film region was measured.
Etching ion source: O₂⁺ (for secondary positive ions) and Cs⁺ (for secondary negative ions)
Acceleration energy of etching ions: 1 keV
Primary ion: Bi⁺
Acceleration energy of primary ion: 25 keV

As the secondary ions, B, Si, In, and Mo were detected as negative ions, and H, F, O, Si, In, and O were detected as positive ions.

The mass resolution was set to normal resolution, and charge correction was performed with an electron gun.

For the secondary ions B and H, concentration conversion was performed using SiO₂ as a standard sample for the SiO₂ region, and concentration conversion was performed using In₂O₃ as a standard sample for the oxide semiconductor region (channel region and impurity region).

Boron concentration distribution for each region or each layer was acquired by the SIMS depth direction analysis described above. The obtained boron concentration distribution was integrated and averaged by the film thickness of each region or each layer to calculate the average boron concentration.

### (C) Evaluation on TFT Performance

The TFTs obtained in Examples and Comparative Examples were measured at room temperature in a light-shielded environment (in a shield box) using a semiconductor parameter analyzer (“B1500” manufactured by Agilent Technologies, Inc.). The drain voltage (Vd) was applied at 0.1 V or 20 V. For each Vd application, the Id-Vg characteristic was obtained by measuring the current value Id in 0.2 V steps of the gate voltage (Vg) from −10 V to 20 V.

Various parameters calculated from the Id-Vg characteristic are shown in Tables 1 to 3. A method of calculating each parameter is as described below.

### (a) Maximum Value (μLin Max) of Linear Mobility

For the maximum value of the linear mobility when Vd=0.1 V is applied, an Id-Vg characteristic graph was created, the transconductance (Gm) of each Vg was calculated, and the linear mobility (μlin) was derived using a formula of a linear region.

Specifically, Gm was calculated by a (Id)/a (Vg).

μlin was calculated by the following formula (c) in the linear region.

$$μ lin = ( Gm \cdot L ) / ( W \cdot Ci \cdot Vd ) \qquad ( c )$$

Ci in the formula (c) is the capacitance of the gate insulating film, and a value of Ci [F/cm²] calculated based on the gate insulating film thickness, the relative permittivity of SiO₂ of 3.9, and the permittivity of vacuum of 8.85×10⁻¹⁴ [F/cm] was used.

L in the formula (c) is a channel length (L length), and W is a channel width (W length).

The maximum value of μlin at Vg=0 to 20 V was calculated from the graph of each Vg-μlin, and was defined as “μlin Max”.

### (b) S Value and Threshold Voltage Vth

The S value and the threshold voltage (Vth) were evaluated from each Id-Vg characteristic graph.

Specifically, in the region of the current value Id=10⁻¹¹ to 10⁻¹⁰ [A], the value obtained by the following formula (d) was calculated as the S value. The value of Vg at the current value Id=10⁻¹⁰ [A] was calculated as the threshold voltage (Vth).

$$S = \frac{Δ Vg}{Δ ( log Id )} \qquad ( d )$$

### (Depth Profile)

Using the time-of-flight secondary ion mass spectrometer (“TOF-SIMS5” manufactured by ION-TOF Corporation) described in the above item (B), an area of about 20 μm×20 μm was designated for the channel region and the impurity region, and SIMS depth direction analysis was performed.

Here, as an example, the depth profile of the boron (B) concentration, the silicon (Si) concentration, and the indium (In) concentration when the impurity region is further specified from the analysis result obtained by performing the SIMS depth direction analysis on the regions of the interlayer insulating film 26-2-second insulating layer 26-1-impurity region 11A-1 of the oxide semiconductor layer 11-buffer layer (first insulating layer) 22 for the TFT device having the same configuration as the thin film transistor (TFT) 60 illustrated in FIG. 7 and obtained by the indirect-implantation-type ion implantation process is shown in FIG. 13. In the graph of FIG. 13, the concentration (atoms/cc) on the left vertical axis represents the average boron concentration (the number of boron atoms per unit volume), the intensity (counts) on the right vertical axis represents the secondary ion intensity of Si⁺ ions and In⁺ ions, and the depth (μm) on the horizontal axis represents the depth.

In FIG. 13, the depth profile of each element described above in the impurity region 11A-1 of the oxide semiconductor layer 11 is 0.22 to 0.26 μm.

The analysis range of the channel region or the impurity region is designated at a position about 1 μm away from the boundary between the channel region and the impurity region in order to avoid detection of components derived from a region other than the analysis target range.

TABLE 1

| | | | Examples/Comparative Examples | | | | | | | |
|---|---|---|---|---|---|---|---|---|---|---|
| | | | Examples | | | | | | | |
| | | | Example number | | | | | | | |
| | | | 1 | 2 | 3 | 4 | 5 | 6 | 7 | 8 |
| TFT | Material | — | A | A | A | A | A | A | A | A |
| production | of oxide | | | | | | | | | |
| method | semiconductor | | | | | | | | | |
| | layer | | | | | | | | | |
| | Film | nm | 30 | 30 | 30 | 30 | 30 | 30 | 30 | 30 |
| | thickness | | | | | | | | | |
| | of oxide | | | | | | | | | |
| | thin film | | | | | | | | | |
| | Ion | — | In- | In- | In- | In- | In- | In- | In- | In- |
| | implantation | | direct | direct | direct | direct | direct | direct | direct | direct |
| | method | | | | | | | | | |
| | (direct/ | | | | | | | | | |
| | indirect) | | | | | | | | | |
| | Implantation | — | Boron | Boron | Boron | Boron | Boron | Boron | Boron | Boron |
| | species | | | | | | | | | |
| | Dose amount | ×10¹⁵ | 3.0 | 1.0 | 2.0 | 2.0 | 2.0 | 0.5 | 1.0 | 1.0 |
| | | (cm⁻²) | | | | | | | | |
| | Beam energy | keV | 30.0 | 30.0 | 20.0 | 30.0 | 40.0 | 30.0 | 30.0 | 30.0 |
| | Substrate | ° C. | Room | Room | Room | Room | Room | 300 | 300 | 200 |
| | temperature | | temper- | temper- | temper- | temper- | temper- | | | |
| | during ion | | ature | ature | ature | ature | ature | | | |
| | implantation | | | | | | | | | |
| Oxide | In-containing | at % | 74 | 74 | 74 | 74 | 74 | 74 | 74 | 74 |
| semi- | amount | | | | | | | | | |
| conductor | | | | | | | | | | |
| layer | | | | | | | | | | |
| Average | Impurity | ×10²⁰ | 3.5 | 1.2 | 1 | 2.3 | 1.8 | 0.58 | 1.2 | 1.2 |
| boron | region | (cm⁻³) | | | | | | | | |
| concen- | of oxide | | | | | | | | | |
| tration | semiconductor | | | | | | | | | |
| | layer | | | | | | | | | |
| | Channel | ×10¹⁸ | — | — | — | — | 2.5 | — | — | — |
| | region | (cm⁻³) | | | | | | | | |
| | of oxide | | | | | | | | | |
| | semiconductor | | | | | | | | | |
| | layer | | | | | | | | | |
| | First | ×10¹⁹ | 10 | 3.5 | 0.2 | 8 | 10 | 1.65 | 3.3 | 3.3 |
| | impurity- | (cm⁻³) | | | | | | | | |
| | added | | | | | | | | | |
| | insulating | | | | | | | | | |
| | film region | | | | | | | | | |
| | Second | ×10²⁰ | 2.3 | 0.8 | 2.5 | 1.5 | 0.5 | 0.38 | 0.8 | 0.8 |
| | impurity- | (cm⁻³) | | | | | | | | |
| | added | | | | | | | | | |
| | insulating | | | | | | | | | |
| | film region | | | | | | | | | |
| | Gate | ×10¹⁹ | — | — | 0.5 | 1.5 | 2.5 | — | — | — |
| | insulating | (cm⁻³) | | | | | | | | |
| | film | | | | | | | | | |
| Conductive | ΔL (½ of | μm | −0.3 | — | 0.75 | 0.7 | −0.2 | 0.51 | 0.89 | 0.7 |
| region | difference | | | | | | | | | |
| character- | between gate | | | | | | | | | |
| istics | width and | | | | | | | | | |
| | effective | | | | | | | | | |
| | channel | | | | | | | | | |
| | length) | | | | | | | | | |
| | Sheet | Ω/□ | 3.65E+02 | 5.36E+03 | 6.53E+02 | 4.47E+02 | 5.25E+02 | 3.02E+03 | 5.91E+02 | 7.88E+02 |
| | resistance | | | | | | | | | |
| | of impurity | | | | | | | | | |
| | region | | | | | | | | | |
| | Specific | Ω cm | 0.001095 | 0.016074 | 0.001959 | 0.001341 | 0.001575 | 0.009054 | 0.001773 | 0.002364 |
| | resistance | | | | | | | | | |
| | of impurity | | | | | | | | | |
| | region | | | | | | | | | |
| TFT | μₗᵢₙ | cm²/Vs | 27.2 | 19.8 | 49.8 | 47.8 | 44.1 | 24.92 | 29.97 | 26.2 |
| character- | Vth | V | −0.36 | 0.33 | −0.89 | −0.06 | 0.55 | −0.03 | −0.69 | −0.27 |
| istics | S value | V/decade | 0.29 | 0.31 | 0.48 | 0.19 | 0.21 | 0.37 | 0.42 | 0.3 |

TABLE 2

| | | | Examples/Comparative Examples | | | | | | | |
|---|---|---|---|---|---|---|---|---|---|---|
| | | | Comparative Examples | | | | | | | |
| | | | Example number | | | | | | | |
| | | | 1 | 2 | 3 | 4 | 5 | 6 | 7 | 8 |
| TFT | Material | — | A | A | A | A | A | A | A | B |
| production | of oxide | | | | | | | | | |
| method | semiconductor | | | | | | | | | |
| | layer | | | | | | | | | |
| | Film | nm | 30 | 30 | 30 | 30 | 30 | 30 | 30 | 20.2 |
| | thickness | | | | | | | | | |
| | of oxide | | | | | | | | | |
| | thin film | | | | | | | | | |
| | Ion | — | Indirect | Indirect | Indirect | Indirect | Indirect | Indirect | Indirect | Indirect |
| | implantation | | | | | | | | | |
| | method | | | | | | | | | |
| | (direct/ | | | | | | | | | |
| | indirect) | | | | | | | | | |
| | Implantation | — | Boron | Boron | Boron | Boron | Boron | Boron | Boron | Argon |
| | species | | | | | | | | | |
| | Dose amount | ×10¹⁵ | 5.0 | 0.5 | 0.1 | 3.0 | 0.1 | 0.5 | 3.0 | 1.0 |
| | | (cm⁻²) | | | | | | | | |
| | Beam energy | keV | 30.0 | 30.0 | 30.0 | 30.0 | 30.0 | 30.0 | 30.0 | 80.0 |
| | Substrate | ° C. | Room | Room | 300 | 300 | 200 | 200 | 200 | Room |
| | temperature | | temper- | temper- | | | | | | temper- |
| | during ion | | ature | ature | | | | | | ature |
| | implantation | | | | | | | | | |
| Oxide | In-containing | at % | 74 | 74 | 74 | 74 | 74 | 74 | 74 | 78 |
| semi- | amount | | | | | | | | | |
| conductor | | | | | | | | | | |
| layer | | | | | | | | | | |
| Average | Impurity | ×10²⁰ | 5.8 | 0.58 | 0.12 | 3.5 | 0.12 | 0.58 | 3.5 | — |
| boron | region | (cm⁻³) | | | | | | | | |
| concen- | of oxide | | | | | | | | | |
| tration | semiconductor | | | | | | | | | |
| | layer | | | | | | | | | |
| | Channel | ×10¹⁸ | — | — | — | — | — | — | — | — |
| | region | (cm⁻³) | | | | | | | | |
| | of oxide | | | | | | | | | |
| | semiconductor | | | | | | | | | |
| | layer | | | | | | | | | |
| | First | ×10¹⁹ | 17 | 1.5 | 0.33 | 10 | 0.33 | 1.65 | 10 | — |
| | impurity- | (cm⁻³) | | | | | | | | |
| | added | | | | | | | | | |
| | insulating | | | | | | | | | |
| | film region | | | | | | | | | |
| | Second | ×10²⁰ | 3.8 | 0.38 | 0.08 | 2.3 | 0.08 | 0.38 | 2.3 | — |
| | impurity- | (cm⁻³) | | | | | | | | |
| | added | | | | | | | | | |
| | insulating | | | | | | | | | |
| | film region | | | | | | | | | |
| | Gate | ×10¹⁹ | — | — | — | — | — | — | — | — |
| | insulating | (cm⁻³) | | | | | | | | |
| | film | | | | | | | | | |
| Conductive | ΔL (½ of | μm | 2.1 | 0.55 | — | 1.38 | — | 0.29 | 2.00 | — |
| region | difference | | | | | | | | | |
| character- | between gate | | | | | | | | | |
| istics | width and | | | | | | | | | |
| | effective | | | | | | | | | |
| | channel | | | | | | | | | |
| | length) | | | | | | | | | |
| | Sheet | Ω/□ | 3.66E+02 | 1.82E+06 | 1.00E+09 | 3.55E+02 | 1.25E+09 | 2.48E+04 | 4.63E+02 | 5.15E+03 |
| | resistance | | | | | | | | | |
| | of impurity | | | | | | | | | |
| | region | | | | | | | | | |
| | Specific | Ω cm | 0.001098 | 5.452116 | 3000 | 0.001065 | 3750 | 0.074343 | 0.001389 | 0.005313 |
| | resistance | | | | | | | | | |
| | of impurity | | | | | | | | | |
| | region | | | | | | | | | |
| TFT | μₗᵢₙ | cm²/Vs | 30.8 | 2.24 | 0.06 | 32.65 | 0.05 | 14.23 | 32.7 | 8.3 |
| character- | Vth | V | −4.3 | −0.29 | 0.3 | <−10 | 0.57 | 0.08 | <−10 | −0.55 |
| istics | S value | V/decade | 0.55 | 0.23 | 0.37 | — | 0.48 | 0.23 | — | 0.19 |

TABLE 3

| | | | Examples/Comparative Examples | | | | | | | | |
|---|---|---|---|---|---|---|---|---|---|---|---|
| | | | Examples | | | Comparative Examples | | | | | |
| | | | Example number | | | | | | | | |
| | | | 9 | 10 | 11 | 9 | 10 | 11 | 12 | 13 | 14 |
| TFT | Material | — | A | B | B | A | A | A | B | B | A |
| production | of oxide | | | | | | | | | | |
| method | semiconductor | | | | | | | | | | |
| | layer | | | | | | | | | | |
| | Film | nm | 30 | 10 | 10 | 30 | 30 | 30 | 10 | 10 | 20.2 |
| | thickness | | | | | | | | | | |
| | of oxide | | | | | | | | | | |
| | thin film | | | | | | | | | | |
| | Ion | — | Direct | Direct | Direct | Direct | Direct | Direct | Direct | Direct | Direct |
| | implantation | | | | | | | | | | |
| | method | | | | | | | | | | |
| | (direct/ | | | | | | | | | | |
| | indirect) | | | | | | | | | | |
| | Implantation | — | Boron | Boron | Boron | Boron | Boron | Boron | Boron | Boron | Argon |
| | species | | | | | | | | | | |
| | Dose amount | ×10¹⁵ | 0.5 | 0.5 | 1.0 | 5.0 | 3.0 | 1.0 | 5.0 | 3.0 | 3.0 |
| | | (cm⁻²) | | | | | | | | | |
| | Beam energy | keV | 5.0 | 5.0 | 5.0 | 5.0 | 5.0 | 5.0 | 5.0 | 5.0 | 40.0 |
| | Substrate | ° C. | Room | Room | Room | Room | Room | Room | Room | Room | Room |
| | temperature | | temper- | temper- | temper- | temper- | temper- | temper- | temper- | temper- | temper- |
| | during ion | | ature | ature | ature | ature | ature | ature | ature | ature | ature |
| | implantation | | | | | | | | | | |
| Oxide | In-containing | at % | 74 | 77 | 77 | 74 | 74 | 74 | 77 | 77 | 74 |
| semi- | amount | | | | | | | | | | |
| conductor | | | | | | | | | | | |
| layer | | | | | | | | | | | |
| Average | Impurity | ×10²⁰ | 1.4 | 1.4 | 2.8 | 13.8 | 8.3 | 2.8 | 13.8 | 8.3 | — |
| boron | region | (cm⁻³) | | | | | | | | | |
| concen- | of oxide | | | | | | | | | | |
| tration | semiconductor | | | | | | | | | | |
| | layer | | | | | | | | | | |
| | Channel | ×10¹⁸ | — | — | — | — | — | — | — | — | — |
| | region | (cm⁻³) | | | | | | | | | |
| | of oxide | | | | | | | | | | |
| | semiconductor | | | | | | | | | | |
| | layer | | | | | | | | | | |
| | First | ×10¹⁹ | 0.2 | 0.4 | 0.8 | 1.7 | 1 | 0.4 | 3.4 | 2 | — |
| | impurity- | (cm⁻³) | | | | | | | | | |
| | added | | | | | | | | | | |
| | insulating | | | | | | | | | | |
| | film region | | | | | | | | | | |
| | Second | ×10²⁰ | wo | wo | wo | wo | wo | wo | wo | wo | wo |
| | impurity- | (cm⁻³) | | | | | | | | | |
| | added | | | | | | | | | | |
| | insulating | | | | | | | | | | |
| | film region | | | | | | | | | | |
| | Gate | ×10¹⁹ | — | — | — | — | — | — | — | — | — |
| | insulating | (cm⁻³) | | | | | | | | | |
| | film | | | | | | | | | | |
| Conductive | ΔL (½ of | μm | 1.05 | 1.7 | 0.85 | 0.75 | 1.65 | 0.7 | 1.1 | — | 0.13 |
| region | difference | | | | | | | | | | |
| character- | between gate | | | | | | | | | | |
| istics | width and | | | | | | | | | | |
| | effective | | | | | | | | | | |
| | channel | | | | | | | | | | |
| | length) | | | | | | | | | | |
| | Sheet | Ω/□ | 5.88E+02 | 1.98E+03 | 3.70E+03 | 7.18E+02 | 8.06E+02 | 4.96E+02 | 3.63E+03 | 2.21E+03 | 9.00E+02 |
| | resistance | | | | | | | | | | |
| | of impurity | | | | | | | | | | |
| | region | | | | | | | | | | |
| | Specific | Ω cm | 0.001764 | 0.001983 | 0.003704 | 0.002154 | 0.002418 | 0.001488 | 0.003634 | 0.002205 | 0.0027 |
| | resistance | | | | | | | | | | |
| | of impurity | | | | | | | | | | |
| | region | | | | | | | | | | |
| TFT | μₗᵢₙ | cm²/Vs | 22.8 | 49.1 | 45.6 | 23 | 25 | 23.3 | 44.8 | 60 | 20.2 |
| character- | Vth | V | −0.57 | −0.56 | −1.4 | −3.7 | −2.7 | −3 | −2.4 | −5.1 | 1.5 |
| istics | S value | V/decade | 0.36 | 0.25 | 0.4 | 0.41 | 0.47 | 0.51 | 0.52 | 0.57 | 0.5 |

In Tables 1 to 3, “-” in the column of the average boron concentration indicates that the average boron concentration was less than the measurement limit value, and “-” in the column of the conductive region characteristic and the TFT characteristics indicates that each characteristic value could not be calculated or the characteristic was very poor and it could not be quantified.

In the TFTs produced in Examples 9 to 11 and Comparative Examples 9 to 14, the second impurity-added insulating film region does not exist, and thus is expressed as “wo” (abbreviation of “without”).

From the results shown in Tables 1 to 3, it has been confirmed that Examples 1 to 11 in which the atomic percent of In contained in the oxide semiconductor layer is 70 atom % or more, and boron ions are contained in the impurity region of the oxide semiconductor layer exhibit high mobility having a high linear mobility of 15 cm²/Vs or more, a high threshold voltage (Vth) of more than −2.4 V, and a small ΔL of 1.7 μm or less, so that favorable switching characteristics can be obtained, and favorable operation as a TFT is achieved.

Although several embodiments and/or examples of the present invention have been described above in detail, for those skilled in the art, it is easy to add numerous modifications to these exemplary embodiments and/or examples without substantially departing from the novel teachings and effects of the present invention. Therefore, many of these modifications fall within the scope of the present invention.

The contents of the literature cited in this specification and the applications on which the present application claims priority under the Paris Convention are incorporated herein by reference in their entirety.

1. A semiconductor device comprising a thin film transistor,
wherein it comprises an oxide semiconductor layer which comprises an impurity region containing boron as an impurity, and
a channel region, and
in which the atomic percent of In is 70 atom % or more based on all metal elements,
a plurality of insulating film layers, and
a plurality of metal layers,
on a substrate,
wherein a linear mobility μₗᵢₙ thereof is 15 cm²/Vs or more, and a threshold voltage Vth thereof is more than −2.4 V.

2. The semiconductor device according to claim 1,
wherein on the substrate,
a first insulating layer,
the oxide semiconductor layer,
a second insulating layer, and
a first metal layer are stacked in this order.

3. The semiconductor device according to claim 1, wherein the atomic percent of In is 73 atom % or more based on all metal elements contained in the oxide semiconductor layer.

4. The semiconductor device according to claim 1, wherein the oxide semiconductor layer comprises a polycrystalline region.

5. The semiconductor device according to claim 1, wherein the oxide semiconductor layer comprises crystal grains having a bixbyite structure.

6. The semiconductor device according to claim 1, wherein a specific resistance of the impurity region is 0.05 Ωcm or less.

7. The semiconductor device according to claim 1, wherein the linear mobility μₗᵢₙ of the channel region is 20 cm²/Vs or more.

8. The semiconductor device according to claim 1, wherein an effective channel length L_{eff} of the channel region is represented by the following formula:
$${L}_{eff} = L - ( Δ {L}_{1} + Δ {L}_{2} )$$
wherein in the formula,
L is a width of a gate electrode in a source electrode-drain electrode direction,
ΔL₁ is a distance from a position where a perpendicular line drawn from one end portion of the gate electrode in a direction of the oxide semiconductor layer intersects the oxide semiconductor layer to an end portion of a region having a carrier concentration that functions as a channel in the oxide semiconductor layer, and
ΔL₂ is a distance from a position where a perpendicular line drawn from the other end portion of the gate electrode in the direction of the oxide semiconductor layer intersects the oxide semiconductor layer to an end portion of a region having a carrier concentration that functions as a channel in the oxide semiconductor layer, and
one or both of ΔL₁ and ΔL₂ are 1.1 μm or less.

9. The semiconductor device according to claim 1, wherein an average boron concentration of the impurity region is 5×10¹⁸ to 5×10²¹ cm⁻³.

10. The semiconductor device according to claim 2, wherein the first insulating layer is in contact with the impurity region of the oxide semiconductor layer,
the first insulating layer has a first impurity-added insulating film region having a thickness up to 100 nm from an interface with the impurity region, and
an average boron concentration of the first impurity-added insulating film region is 1×10¹⁷ to 3×10²¹ cm⁻³.

11. The semiconductor device according to claim 2, wherein the second insulating layer is in contact with the impurity region on a surface of the oxide semiconductor layer on a side opposite to a contact surface with the first insulating layer,
the second insulating layer has a second impurity-added insulating film region, and
an average boron concentration of the second impurity-added insulating film region is 5×10¹⁸ to 5×10²¹ cm⁻³.

12. The semiconductor device according to claim 1, wherein an average boron concentration of the channel region is less than 5×10¹⁸ cm⁻³.

13. The semiconductor device according to claim 11, wherein the second insulating layer comprises the second impurity-added insulating film region and a gate insulating film region having an insulating property.

14. The semiconductor device according to claim 13, wherein an average boron concentration of the gate insulating film region is 1×10¹⁷ to 5×10²⁰ cm⁻³.

15. The semiconductor device according to claim 1, which is a thin film transistor.

16. An electronic circuit comprising the semiconductor device according to claim 1.

17. An electric apparatus, an electronic apparatus, a vehicle, or a power engine, comprising the electronic circuit according to claim 16.
